(19) United States
(12) Patent Application Publication
(10) Pub. No.: US 2012/0313729 A1
(43) Pub. Date: Dec. 13, 2012

(54) LC COMPOSITE COMPONENT AND STRUCTURE FOR MOUNTING LC COMPOSITE COMPONENT

(75) Inventor: Masaaki TOGASHI, Tokyo (JP)

(73) Assignee: TDK CORPORATION, Tokyo (JP)

(21) Appl. No.: 13/479,929

(22) Filed: May 24, 2012

(30) Foreign Application Priority Data
Jun. 9, 2011 (JP) 2011-129421

(51) Int. Cl. H05K 1/16; H03H 5/00

(52) U.S. Cl. 333/184; 333/24 R

(57) ABSTRACT

An LC composite component is provided in which a capacitor section and an inductor section are alternately stacked in layers in the layering direction; either the capacitor section or the inductor section is disposed on both a first element body principal face side and a second element body principal face side; a first coil wire path portion and a second coil wire path portion are connected to an external conductor interposed between an external conductor near a first element body end face and an external conductor near a second element body end face in a first external conductor group; and the first coil wire path portion and the second coil wire path portion form a coil which is wound in a helical fashion along the layering direction.

### CROSS-REFERENCE TO RELATED APPLICATIONS

This application is based upon and claims the benefit of priority from Japanese Patent Application No. 2011-129421, filed on Jun. 9, 2011, the entire contents of which are incorporated herein by reference.

### BACKGROUND OF THE INVENTION

1. Field of the Invention

The present invention relates to an LC composite component to be mounted on circuit boards and to a structure for mounting the LC composite component.

2. Description of the Related Art

Electronic appliances such as personal computers, personal digital assistants (PDAs), or cellular phones may include a circuit board on which a composite component having a combination of a capacitor and an inductor is surface mounted. For example, disclosed in Patent Literature 1 is a π-type LC composite EMI filter employed as an LC composite component.

The LC composite component disclosed in Patent Literature 1 (Japanese Patent Application Laid-Open No. 2005-252456) has no mounting directivity and selectively removes noises within a specific frequency region in an electronic appliance. However, recent LC composite components are desired to have an increased inductance component.

### SUMMARY OF THE INVENTION

According to an aspect of the present invention, there is provided an LC composite component including; an element body; a first external conductor group; a second external conductor group; a capacitor section; and an inductor section, wherein the element body includes: a plurality of insulator layers stacked in layers; a first element body principal face and a second element body principal face which intersect a layering direction of the plurality of insulator layers; a first element body side face and a second element body side face which couple the first element body principal face and the second element body principal face and which are opposed to each other; and a first element body end face and a second element body end face which couple the first element body principal face and the second element body principal face together as well as the first element body side face and the second element body side face and which are opposed to each other; wherein the first external conductor group has three or more external conductors, each being disposed on the first element body side face, and the second external conductor group has three or more external conductors, each being disposed on the second element body side face; wherein the capacitor section has a first internal electrode and a second internal electrode which are formed on the insulator layers and which are opposed to each other in the layering direction, the first internal electrode being drawn out to the first element body side face and connected to at least one of the external conductors of the first external conductor group, the second internal electrode being drawn out to the second element body side face and connected to at least one of the external conductors of the second external conductor group; and wherein the inductor section has a first coil wire path portion and a second coil wire path portion which are each formed on any one of the plurality of insulator layers and which are each an electrical conductor pattern, wherein the capacitor section and the inductor section are alternately stacked in layers in the layering direction, and either one of the capacitor section and the inductor section is disposed both on the first element body principal face side and the second element body principal face side, and wherein the first coil wire path portion and the second coil wire path portion are connected to the external conductor interposed between the external conductor near the first element body end face and the external conductor near the second element body end face in the first external conductor group, or connected to the external conductor interposed between the external conductor near the first element body end face and the external conductor near the second element body end face in the second external conductor group, and the first coil wire path portion and the second coil wire path portion serve as a coil which is wound in a helical fashion along the layering direction.

### BRIEF DESCRIPTION OF THE DRAWINGS

FIG. 1 is a perspective view illustrating an LC composite component according to the embodiments;

FIG. 2 is an exploded perspective view illustrating the main portion of the element body of an LC composite component according to a first embodiment;

FIG. 3 is a cross-sectional view illustrating the element body of the LC composite component according to the first embodiment;

FIG. 4 is a cross-sectional view illustrating the element body of the LC composite component according to the first embodiment;

FIG. 5 is an explanatory view illustrating an equivalent circuit of the LC composite component according to the first embodiment;

FIG. 6 is an explanatory view illustrating an example of connection between the LC composite component according to the first embodiment and signal lines;

FIG. 7 is an exploded perspective view illustrating the main portion of the element body of an LC composite component according to a second embodiment;

FIG. 8 is an exploded perspective view illustrating the main portion of the element body of an LC composite component according to a first modified example of the second embodiment;

FIG. 9 is a cross-sectional view illustrating the element body of the LC composite component according to the first modified example of the second embodiment;

FIG. 10 is an exploded perspective view illustrating the main portion of the element body of an LC composite component according to a second modified example of the second embodiment;

FIG. 11 is a cross-sectional view illustrating the element body of the LC composite component according to the second modified example of the second embodiment;

FIG. 12 is an exploded perspective view illustrating the main portion of the element body of an LC composite component according to a third modified example of the second embodiment;

FIG. 13 is a cross-sectional view illustrating the element body of the LC composite component according to the third modified example of the second embodiment;

FIG. 14 is an exploded perspective view illustrating the main portion of the element body of an LC composite component according to a third embodiment;

FIG. 15 is an explanatory view illustrating an equivalent circuit of the LC composite component according to the third embodiment;

FIG. 16 is an explanatory view illustrating an example of connection between the LC composite component according to the third embodiment and signal lines;

FIG. 17 is an exploded perspective view illustrating the main portion of the element body of an LC composite component according to a fourth embodiment;

FIG. 18 is an exploded perspective view illustrating the main portion of the element body of an LC composite component according to a fifth embodiment;

FIG. 19 is an explanatory view illustrating an equivalent circuit of the LC composite component according to the fifth embodiment;

FIG. 20 is an explanatory view illustrating an example of connection between the LC composite component according to the fifth embodiment and signal lines; and

FIG. 21 is an exploded perspective view illustrating the main portion of the element body of an LC composite component according to a sixth embodiment.

### DETAILED DESCRIPTION OF THE PREFERRED EMBODIMENTS

The present invention will be described in detail below in accordance with the modes for carrying out the invention (embodiments) with reference to the drawings. The present invention will not be limited to the contents described in the embodiments below. Furthermore, the components described below may include those that one skilled in the art can readily assume or those that are substantially identical. Furthermore, the components to be described below can be combined as appropriate.

It is an object of embodiments of the present invention to provide an LC composite component which has no mounting directivity and which has an increased inductance component, and a structure for mounting the LC composite component.

### First Embodiment

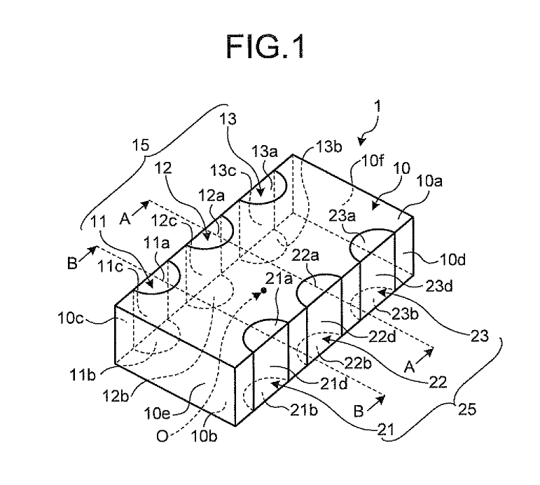

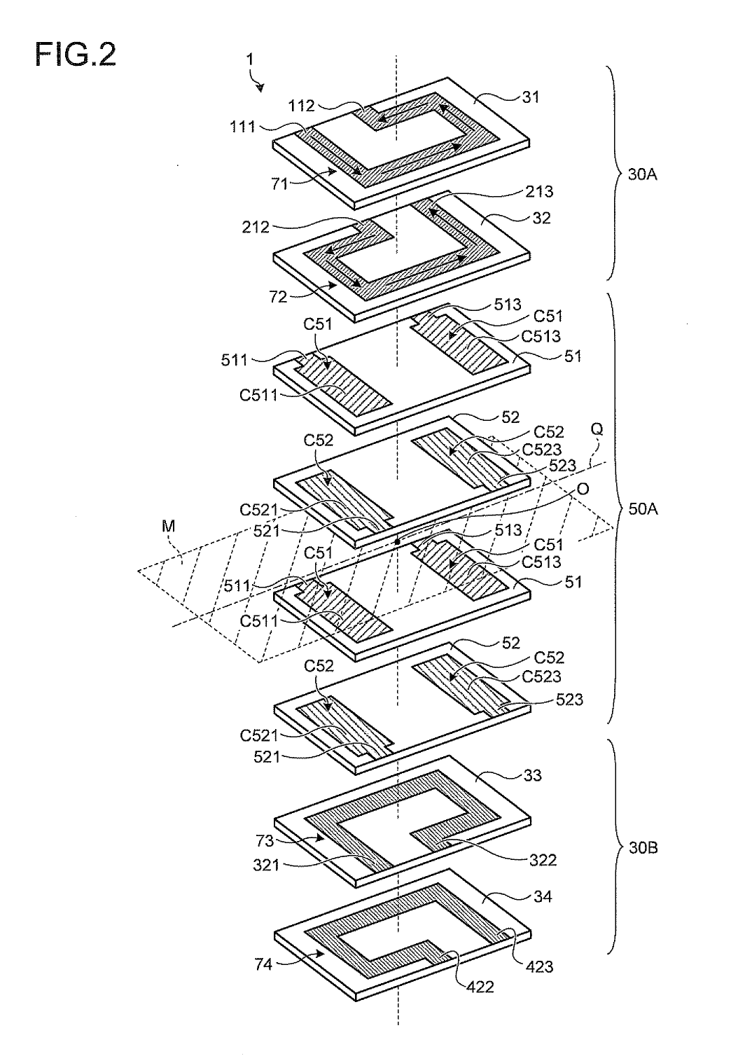

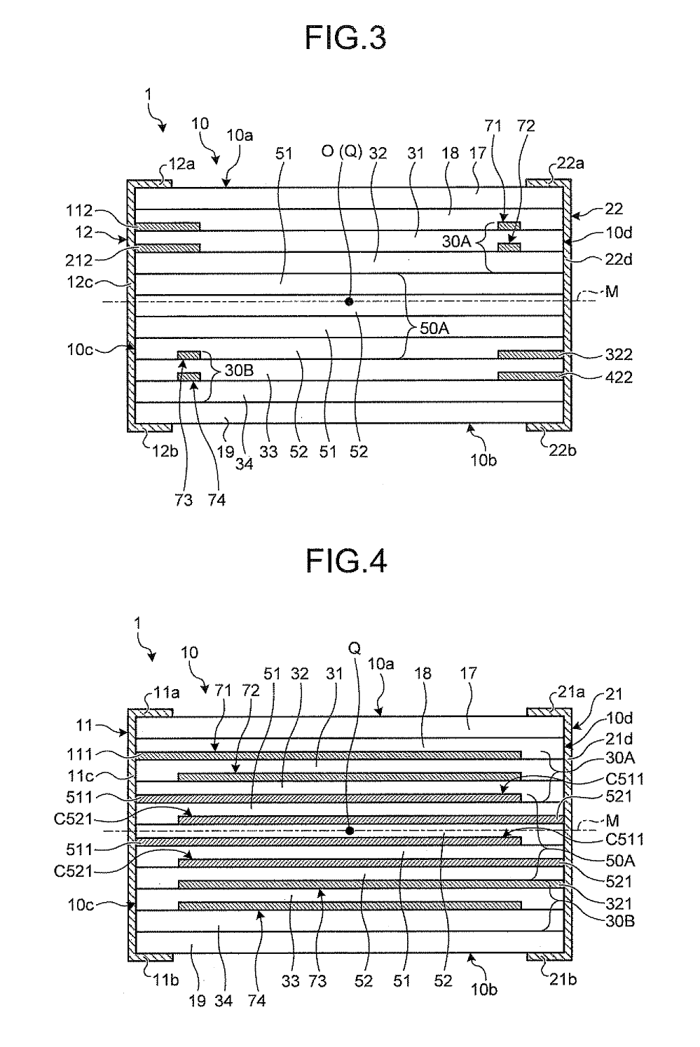

FIG. 1 is a perspective view illustrating an LC composite component according to the embodiments. FIG. 2 is an exploded perspective view illustrating the main portion of the element body of an LC composite component according to a first embodiment. FIGS. 3 and 4 are cross-sectional views illustrating the element body of the LC composite component according to the first embodiment. FIG. 2 illustrates an element body 10 of an LC composite component 1 which is decomposed in the order of layering, excluding insulator layers 17, 18, and 19, to be described later, which are to serve as a first element body principal face 10a or a second element body principal face 10b of the element body 10. FIG. 3 is a cross-sectional view taken along line A-A of FIG. 1. FIG. 4 is a cross-sectional view taken along line B-B of FIG. 1.

The LC composite component 1 includes a capacitor section 50A for accumulating or discharging capacitance; a first inductor section 30A in which predetermined inductance operates; and a second inductor section 30B. The LC composite component 1 has the element body 10; and external conductors 11, 12, 13, 21, 22, and 23 which are formed on the surface of the element body 10.

The element body 10 of the LC composite component 1 has the shape of a generally rectangular parallelepiped. This allows the LC composite component 1 to have the first element body principal face 10a and the second element body principal face 10b of the element body 10 which are opposed to each other in the layering direction in which the first inductor section 30A, the capacitor section 50A, and the second inductor section 30B are stacked in layers as shown in FIG. 2. The LC composite component 1 is mounted on a circuit board in a manner such that either the first element body principal face 10a or the second element body principal face 10b is placed on the circuit board as the mounted surface.

The element body 10 has an element body center O which is located at the center between the conductors on the both sides in the layering direction and at which the diagonal lines of a quadrangle intersect, the quadrangle having, as vertices, two external conductors located near a first element body end portion 10e and two external conductors located near a second element body end portion 10f. Furthermore, the element body center O is located on an element body center plane M, which is a virtual plane orthogonal to the layering direction. As shown in FIG. 1, the conductor nearest to the first element body principal face 10a and the conductor nearest to the second element body principal face 10b correspond to the conductors on the both sides in the layering direction (element body principal face side conductors). For example, the center between the conductors on the both sides in the layering direction can be defined as the equidistant position from both the surfaces of the respective element body principal face side conductors, one of the surfaces being on the first element body principal face 10a side and the other being on the second element body principal face 10b side. Furthermore, to determine the intersection of the diagonal lines, for example, the vertices can be defined as the midpoints of the external conductors along the longer side of the first element body principal face 10a or the second element body principal face, which is rectangular when viewed from above.

The LC composite component 1 has a first element body side face 10c and a second element body side face 10d, which couple together the first element body principal face 10a and the second element body principal face 10b and which are opposed to each other. The LC composite component 1 also has a first element body end face 10e and a second element body end face 10f, which couple together the first element body principal face 10a and the second element body principal face 10b as well as the first element body side face 10c and the second element body side face 10d and which are opposed to each other.

The LC composite component 1 is configured such that the first element body side face 10c and the second element body side face 10d extend in the direction of the longer sides of the first element body principal face 10a and in the direction of the longer sides of the second element body principal face 10b, while the first element body end face 10e and the second element body end face 10f extend in the direction of the shorter sides of the first element body principal face 10a and in the direction of the shorter sides the second element body principal face 10b. Note that as a modified example, the LC composite component 1 may also be configured such that the first element body side face 10c and the second element body side face 10d can extend in the direction of the shorter sides of the first element body principal face 10a and in the direction of the shorter sides of the second element body principal face 10b while the first element body end face 10e and the second element body end face 10f can extend in the direction of the longer sides of the first element body principal face 10a and in the direction of the longer sides of the second element body principal face 10b. Furthermore, the first element body principal face 10a and the second element body principal face 10b may also be square in shape.

A set of external conductors 11, 12, and 13 are included in a first external conductor group 15, the conductors being spaced apart from each other by a predetermined distance and disposed on the first element body side face 10c side. A set of external conductors 21, 22, and 23 are included in a second external conductor group 25, the conductors being spaced apart from each other by a predetermined distance and disposed on the second element body side face 10d side. The external conductors 11, 12, and 13, and the external conductors 21, 22, and 23 are disposed at least on the surfaces of the first element body side face 10c and the second element body side face 10d with the element body 10 therebetween. That is, the first external conductor group 15 and the second external conductor group 25 are opposed to each other with the element body 10 therebetween in the direction in which the first element body side face 10c and the second element body side face 10d are opposed to each other. Note that the first external conductor group 15 and the second external conductor group 25 each only have to include three or more external conductors.

The external conductors 11, 12, 13, 21, 22, and 23 have terminal portions 11a, 12a, 13a, 21a, 22a, and 23a, and 11b, 12b, 13b, 21b, 22b, and 23b on each one of the first element body principal face 10a and the second element body principal face 10b. The terminal portions 11a, 12a, 13a, 21a, 22a, and 23a, and the terminal portions 11b, 12b, 13b, 21b, 22b, and 23b are opposed to each other with the element body 10 therebetween in the direction in which the first element body principal face 10a and the second element body principal face 10b are opposed to each other. The terminal portions 11a, 12a, 13a, 21a, 22a, and 23a, and the terminal portions 11b, 12b, 13b, 21b, 22b, and 23b preferably allow the opposing terminal portions to have the same area.

On the first element body side face 10c and the second element body side face 10d, the external conductors 11, 12, 13, 21, 22, and 23 have external conductor portions 11c, 12c, 13c, 21d, 22d, and 23d which electrically connect between the terminal portions 11a, 12a, 13a, 21a, 22a, and 23a, and the terminal portions 11b, 12b, 13b, 21b, 22b, and 23b, respectively. The external conductor portions 11c, 12c, and 13c are formed on the surface of the first element body side face 10c. On the other hand, the external conductor portions 21d, 22d, and 23d are formed on the surface of the second element body side face 10d.

The LC composite component 1 is preferably configured such that the terminal portions 11a, 12a, 13a, 21a, 22a, and 23a on the first element body principal face 10a and the terminal portions 11b, 12b, 13b, 21b, 22b, and 23b on the second element body principal face 10b should be arranged in the same manner. This allows the LC composite component 1 to be mounted on a circuit board even with any one of the first element body principal face 10a and the second element body principal face 10b being opposed to the circuit board.

The external conductors 11, 12, and 13 of the first external conductor group 15 and the external conductors 21, 22, and 23 of the second external conductor group 25 are disposed so as to be symmetric with respect to the element body center O when the first element body principal face 10a is viewed in the layering direction. This can eliminate the mounting directivity within the circuit board plane.

The external conductors 11, 12, 13, 21, 22, and 23 are formed, for example, by applying an electrically conductive paste containing electrical conductive metal powder to the surface of the element body 10 and then baking the same thereon. If required, a plating layer may be formed on a baked electrode.

As shown in FIG. 2, the LC composite component 1 is configured such that the capacitor section and the inductor sections are alternately stacked in layers in the order of the first inductor section 30A, the capacitor section 50A, and the second inductor section 30B. The LC composite component 1 is designed such that the first inductor section 30A and the second inductor section 30B are symmetric with respect to the capacitor section 50A in the layering direction. This allows the first inductor section 30A and the second inductor section 30B to be located near the first element body principal face 10a and the second element body principal face 10b of the LC composite component 1, respectively.

As shown in FIGS. 3 and 4, the LC composite component 1 is configured such that the element body 10 is formed by stacking insulator layers 17, 18, 31, 32, 51, 52, 51, 52, 33, 34, and 19 from the first element body principal face 10a to the second element body principal face 10b. The insulator layers 17, 18, and 19 are outer layers to cover the capacitor section 50A and the first inductor section 30A, and the second inductor section 30B. The insulator layers 17, 18, and 19 are preferably formed of dielectric such as barium titanate (BaTiO₃) or magnetic substance such as ferrite.

The total thickness determined by adding up in the layering direction the thicknesses of the insulator layer 17 and the insulator layer 18, shown in FIGS. 3 and 4, may or may not be the same as or is more preferably the same as the total thickness determined by adding up in the layering direction the thicknesses of the insulator layer 34 and the insulator layer 19. Even with any one of the first element body principal face 10a and the second element body principal face 10b being opposed to the circuit board, this structure allows the LC composite component 1 to have generally the same distances from the circuit board to the aforementioned element body principal face side conductors. Accordingly, the resistances of the external conductors 11, 12, and 13 of the first external conductor group 15 and the external conductors 21, 22, and 23 of the second external conductor group 25 are generally the same even when any one of the first element body principal face 10a and the second element body principal face 10b is opposed to the circuit board.

The first inductor section 30A shown in FIG. 2 has the insulator layers 31 and 32; electrically conductive extraction electrode portions 111, 112, 212, and 213 formed on the respective insulator layers 31 and 32; an electrically conductive first coil wire path portion 71 formed on the insulator layer 31; and an electrically conductive second coil wire path portion 72 formed on the insulator layer 32.

The second inductor section 30B shown in FIG. 2 has the insulator layers 33 and 34; electrically conductive extraction electrode portions 321, 322, 422, and 423 formed on the respective insulator layers 33 and 34; an electrically conductive second coil wire path portion 73 formed on the insulator layer 33; and an electrically conductive first coil wire path portion 74 formed on the insulator layer 34. The extraction electrode portions 111, 112, 212, 213, 321, 322, 422, and 423, the first coil wire path portions 71 and 74, and the second coil wire path portions 72 and 73 are formed, for example, of palladium, a silver/palladium alloy, nickel, or copper (Cu). The first inductor section 30A can have the insulator layers 31 and 32 or the second inductor section 30B can have the insulator layers 33 and 34 with no limitation on the number of layers to be stacked.

The insulator layers 31 and 32 extend in a direction parallel to the first element body principal face 10a and the second element body principal face 10b, and are stacked adjacent to each other in the order of the insulator layers 31 and 32 from the first element body principal face 10a toward the second element body principal face 10b. The same holds true for the insulator layers 33 and 34. The insulator layers 31, 32, 33, and 34 are preferably formed of a dielectric material such as barium titanate (BaTiO₃) or a magnetic substance material such as ferrite. The insulator layers 31, 32, 33, and 34 formed of a dielectric material such as barium titanate employ the same material as that of the insulator layers 51, 52, 51, and 52 of the capacitor section 50A, to be described later, thereby reducing stress resulting from contraction during baking.

On the other hand, the insulator layers 31, 32, 33, and 34 formed of magnetic substance such as ferrite are capable of improving the inductance of the first coil wire path portions 71 and 74 and the second coil wire path portions 72 and 73.

The extraction electrode portions 111 and 112 are formed on the surface of the insulator layer 31 located near the first element body principal face 10a. The extraction electrode portions 111 and 112 are spaced apart from each other by a predetermined distance so as to be electrically insulated from each other on the surface of the insulator layer 31. This distance is the same as the distance between the adjacent external conductor portions 11c and 12c. The extraction electrode portions 111 and 112 are disposed on the first element body side face 10c side and drawn out to the first element body side face 10c.

The first coil wire path portion 71 is formed on the surface of the insulator layer 31. The extraction electrode portions 111 and 112 are an end portion of the first coil wire path portion 71 and serve as an extraction trace to draw out the first coil wire path portion 71 to the first element body side face 10c. The first coil wire path portion 71 has a one-turn coil pattern in which an electrical conductor connecting between the extraction electrode portion 111 and the extraction electrode portion 112 is wound on the surface of the insulator layer 31 along the first element body end face 10e, the second element body side face 10d, the second element body end face 10f, and the first element body side face 10c, in that order.

The extraction electrode portions 212 and 213 are formed on the surface of the insulator layer 32. The extraction electrode portions 212 and 213 are spaced apart from each other by a predetermined distance so as to be electrically insulated from each other on the surface of the insulator layer 32. This distance is the same as the distance between the adjacent external conductor portions 12c and 13c. The extraction electrode portions 212 and 213 are disposed on the first element body side face 10c side and drawn out to the first element body side face 10c.

The second coil wire path portion 72 is formed on the surface of the insulator layer 32. The extraction electrode portions 212 and 213 are an end portion of the second coil wire path portion 72 and serve as an extraction trace to draw out the second coil wire path portion 72 to the first element body side face 10c. The second coil wire path portion 72 has a one-turn coil pattern in which an electrical conductor connecting between the extraction electrode portion 212 and the extraction electrode portion 213 is wound on the surface of the insulator layer 32 along the first element body side face 10c, the first element body end face 10e, the second element body side face 10d, and the second element body end face 10f, in that order.

As shown in FIG. 3, the first inductor section 30A is configured such that the extraction electrode portion 112 and the extraction electrode portion 212 are connected to each other by the external conductor portion 12c. Furthermore, as shown in FIG. 4, the extraction electrode portion 111 is electrically connected to the external conductor portion 11c. Furthermore, the extraction electrode portion 213 shown in FIG. 2 is electrically connected to the external conductor portion 13c shown in FIG. 1.

The first inductor section 30A is configured such that the first coil wire path portion 71 and the second coil wire path portion 72 are connected to each other via the external conductor portion 12c. This allows the external conductor portion 12c to serve as the external connection conductor for coupling between the first coil wire path portion 71 and the second coil wire path portion 72. The LC composite component 1 has a spiral coil of the first coil wire path portion 71 and the second coil wire path portion 72 which are wound in a helical fashion along the layering direction.

Suppose, for example, that n coil wire path portions exist. In this case, n+1 external conductors are included in the first external conductor group 15. Here, to provide a spiral coil, n is two or more. The LC composite component 1 is not limited to the case of n=2, but may also be n=3 or greater. In this case, n−1 external conductors, which can be employed as an external connection conductor, are present between the external conductor near the first element body end face 10e and the external conductor near the second element body end face 10f. The adjacent coil wire path portions in the layering direction are connected to each other by different external connection conductors. Then, the n coil wire path portions form a spiral coil that is wound in a helical fashion along the layering direction. The number of coil wire path portions to be stacked in layers can be increased to provide a greater number of turns. Furthermore, the spiral coils are wound in the same direction and may be wound in a clockwise or counterclockwise direction.

It is also conceivable to connect between the first coil wire path portion 71 and the second coil wire path portion 72 via through holes in place of the external connection conductor. However, in this case, the electrically conductive pattern of the first coil wire path portion 71 or the second coil wire path portion 72 would have to be routed so as to detour the through holes.

The LC composite component 1 can provide a spiral coil with an electrically conductive path of an elongated total length, the spiral coil including the first coil wire path portion 71 and the second coil wire path portion 72, by connecting between the first coil wire path portion 71 and the second coil wire path portion 72 via the external connection conductor. Furthermore, the LC composite component 1 is configured such that the electrically conductive path of the spiral coil which is formed by connecting between the first coil wire path portion 71 and the second coil wire path portion 72 via the external connection conductor is longer than the electrically conductive path of the spiral coil which is formed by connecting between the first coil wire path and the second coil wire path via the through hole.

Now, a description will be made to the second inductor section 30B shown in FIG. 2. The extraction electrode portions 321 and 322 are formed on the surface of the insulator layer 33. The extraction electrode portions 321 and 322 are spaced apart from each other by a predetermined distance so as to be electrically insulated from each other on the surface of the insulator layer 33. This distance is the same as the distance between the adjacent external conductor portions 21d and 22d. The extraction electrode portions 321 and 322 are disposed on the second element body side face 10d side and drawn out to the second element body side face 10d.

The second coil wire path portion 73 is formed on the surface of the insulator layer 33. The extraction electrode portions 321 and 322 are an end portion of the second coil wire path portion 73 and serve as an extraction trace to draw out the second coil wire path portion 73 to the second element body side face 10d. The second coil wire path portion 73 has a one-turn coil pattern in which an electrical conductor connecting between the extraction electrode portion 321 and the extraction electrode portion 322 is wound on the surface of the insulator layer 33 along the first element body end face 10e, the first element body side face 10c, the second element body end face 10f, and the second element body side face 10d, in that order.

The extraction electrode portions 422 and 423 are formed on the surface of the insulator layer 34 located near the second element body principal face 10b. The extraction electrode portions 422 and 423 are spaced apart from each other by a predetermined distance so as to be electrically insulated from each other on the surface of the insulator layer 34. This distance is the same as the distance between the adjacent external conductor portions 22d and 23d. The extraction electrode portions 422 and 423 are disposed on the second element body side face 10d side and drawn out to the second element body side face 10d.

The first coil wire path portion 74 is formed on the surface of the insulator layer 34. The extraction electrode portions 422 and 423 are an end portion of the first coil wire path portion 74 and serve as an extraction trace to draw out the first coil wire path portion 74 to the second element body side face 10d. The first coil wire path portion 74 has a one-turn coil pattern in which an electrical conductor connecting between the extraction electrode portion 422 and the extraction electrode portion 423 is wound on the surface of the insulator layer 34 along the second element body side face 10d, the first element body end face 10e, the first element body side face 10c, and the second element body end face 10f, in that order.

As shown in FIG. 3, the second inductor section 30B is configured such that the extraction electrode portion 322 and the extraction electrode portion 422 are connected to each other by the external conductor portion 22d. Furthermore, as shown in FIG. 4, the extraction electrode portion 321 is electrically connected to the external conductor portion 21d. In the same manner, the extraction electrode portion 423 shown in FIG. 2 is electrically connected to the external conductor portion 23d shown in FIG. 1.

The second inductor section 30B is configured such that the second coil wire path portion 73 and the first coil wire path portion 74 are connected to each other via the external conductor portion 22d. This allows the external conductor portion 22d to serve as the external connection conductor for coupling between the first coil wire path portion 74 and the second coil wire path portion 73. The LC composite component 1 has a spiral coil of the second coil wire path portion 73 and the first coil wire path portion 74 which are wound in a helical fashion along the layering direction.

The first coil wire path portion 74 of the second inductor section 30B and the first coil wire path portion 71 of the first inductor section 30A are disposed to be symmetric with respect to the element body center O of the element body 10 when viewed in the layering direction. On the other hand, the second coil wire path portion 73 of the second inductor section 30B and the second coil wire path portion 72 of the first inductor section 30A are disposed to be symmetric with respect to the element body center O of the element body 10 when viewed in the layering direction.

Furthermore, it is preferable that the thicknesses of the insulator layer 31 and the insulator layer 34 should be the same while the thicknesses of the insulator layer 32 and the insulator layer 33 should be the same. This allows the length between the extraction electrode portions 112 and 212, which the external conductor portion 12c connects, and the length between the extraction electrode portions 322 and 422, which the external conductor portion 22d connects, to be the same. As a result, the inductor section 30A and the inductor section 30B are found to be the multilayer inductors that have the same inductance.

Note that it is preferable that the first inductor section 30A and the second inductor section 30B should have the same number of coil wire path portions. Furthermore, n coil wire path portions present in the second inductor section 30B would be identical to n coil wire path portions present in the aforementioned first inductor section 30A.

The capacitor section 50A shown in FIG. 2 is formed on the surface of the insulator layers 51 and 52, and includes first internal electrodes C51 formed on the surface of the insulator layer 51 and second internal electrodes C52 formed on the surface of the insulator layer 52. The first internal electrodes C51 each have an extraction electrode portion 511 or 513 which is formed of electrical conductor on the surface of the insulator layer 51, and a first principal face electrode portion C511 or C513 which is also formed of electrical conductor on the surface of the insulator layer 51. The second internal electrodes C52 each have an extraction electrode portion 521 or 523 formed of electrical conductor on the surface of the insulator layer 52, and a second principal face electrode portion C521 or C523 formed of electrical conductor on the surface of the insulator layer 52.

The extraction electrode portions 511 and 513 of the first internal electrodes C51 are drawn out to the first element body side face 10c and connected to the external conductors 11 and 13 of the first external conductor group 15 shown in FIG. 1. On the other hand, the extraction electrode portions 521 and 523 of the second internal electrodes C52 are drawn out to the second element body side face 10d and connected to the external conductors 21 and 23 of the second external conductor group 25 shown in FIG. 1.

The extraction electrode portions 511, 513, 521, and 523, the first principal face electrode portions C511 and C513, and the second principal face electrode portions C521 and C523 are formed of, for example, palladium, a silver/palladium alloy, nickel, or copper (Cu). In this embodiment, the capacitor section 50A has the insulator layers 51, 52, 51, and 52 which are stacked in layers in that order from the first element body principal face 10a toward the second element body principal face 10b. The capacitor section 50A includes at least one “unit of capacitor” (capacitor unit) which has the first internal electrodes C51, the insulator layer 51, the second internal electrodes C52, and the insulator layer 52 stacked in layers in that order. The capacitor section 50A only has to include such a number of capacitor units that can provide the capacitance required of the specification of the LC composite component 1, with no limitation on the number. Furthermore, the insulator layers 51 and 52 of the capacitor section 50A are preferably a dielectric layer which contains a dielectric material such as barium titanate. This structure can provide increased capacitance.

The extraction electrode portions 511 and 513 are formed on the surface of the insulator layer 51. The extraction electrode portions 511 and 513 are spaced apart from each other by a predetermined distance so as to be electrically insulated from each other on the surface of the insulator layer 51. This distance is the same as the distance between the adjacent external conductor portions 11c and 13c. The extraction electrode portions 511 and 513 are disposed near the first element body side face 10c. This allows the extraction electrode portion 511 to be electrically connected to the external conductor portion 11c. This also allows the extraction electrode portion 513 to be electrically connected to the external conductor portion 13c.

The extraction electrode portions 511 and 513 are electrically connected to the first principal face electrode portions C511 and C513, respectively. The first principal face electrode portions C511 and C513 are formed on the surface of the insulator layer 51. The first principal face electrode portions C511 and C513 are spaced apart from each other by a predetermined distance so as to be electrically insulated from each other on the surface of the insulator layer 51, and have a greater area than that of the extraction electrode portions 511 and 513.

The extraction electrode portions 521 and 523 are formed on the surface of the insulator layer 52. The extraction electrode portions 521 and 523 are spaced apart from each other by a predetermined distance so as to be electrically insulated from each other on the surface of the insulator layer 52. This distance is the same as the distance between the external conductor portions 21d and 23d. The extraction electrode portions 521 and 523 are disposed near the second element body side face 10d. This allows the extraction electrode portion 521 to be electrically connected to the external conductor portion 21d. This also allows the extraction electrode portion 523 to be electrically connected to the external conductor portion 23d.

The extraction electrode portions 521 and 523 are electrically connected to the second principal face electrode portions C521 and C523, respectively. The principal face electrode portions C521 and C523 are formed on the surface of the insulator layer 52. The principal face electrode portions C521 and C523 are spaced apart from each other by a predetermined distance so as to be electrically insulated from each other on the surface of the insulator layer 52 and have a greater area than that of the extraction electrode portions 511 and 513.

As described above, the capacitor section 50A is configured such that the first principal face electrode portions C511 and C513, and the second principal face electrode portions C521 and C523 are drawn out via the extraction electrode portions 511 and 513 and the extraction electrode portions 521 and 523 to the first element body side face 10c and the second element body side face 10d which are opposite in direction to each other. The capacitor section 50A is also configured such that the principal face electrode portion C511 and the principal face electrode portion C521 are opposed to each other in the layering direction via an insulator. Furthermore, the principal face electrode portion C511 is not opposed to the principal face electrode portion C523. Accordingly, no unnecessary capacitance will be developed. The capacitor section 50A is configured such that the principal face electrode portion C513 and the principal face electrode portion C523 are opposed to each other in the layering direction via an insulator. Furthermore, the principal face electrode portion C513 is not opposed to the principal face electrode portion C521. Accordingly, no unnecessary capacitance will be developed.

This allows the capacitor section 50A to serve as a multilayer capacitor in which capacitance will be developed between the principal face electrode portions C511 and C513 and the principal face electrode portions C521 and C523.

As shown in FIGS. 2 to 4, the first inductor section 30A and the second inductor section 30B are separately disposed above and below the element body center plane M in the layering direction. The LC composite component 1 is configured such that the first internal electrodes C51 and the second internal electrodes C52 are disposed at the same position and the same distance with respect to the element body center O.

The LC composite component 1 is also configured such that the first coil wire path portion 71 of the first inductor section 30A and the first coil wire path portion 74 of the second inductor section 30B are disposed at the same position and the same distance with respect to the element body center O. In the same manner, the second coil wire path portion 72 of the first inductor section 30A and the second coil wire path portion 73 of the second inductor section 30B are also disposed at the same position and the same distance.

Alternatively, the LC composite component 1 may also be configured such that the first coil wire path portion 71 of the first inductor section 30A and the second coil wire path portion 73 of the second inductor section 30B are disposed at the same position and the same distance with respect to the element body center O. In the same manner, the second coil wire path portion 72 of the first inductor section 30A and the first coil wire path portion 74 of the second inductor section 30B may also be disposed at the same position and the same distance.

In other words, the first coil wire path portion 71 of the first inductor section 30A and either the second coil wire path portion 73 or the first coil wire path portion 74 of the second inductor section 30B are symmetric with respect to a center line Q which passes through the intermediate position on the element body center plane M between the first element body side face 10c and the second element body side face 10d. Accordingly, the first coil wire path portion 71 has an electrically conductive pattern which when rotated about the center line Q, overlaps that of the first coil wire path portion 74 or the second coil wire path portion 73. In this embodiment, the first coil wire path portion 71 of the first inductor section 30A and the second coil wire path portion 73 of the second inductor section 30B are symmetric with respect to the center line Q.

Furthermore, the second coil wire path portion 72 of the first inductor section 30A and one of the second coil wire path portion 73 and the first coil wire path portion 74 of the second inductor section 30B are symmetric with respect to the center line Q, the one and the first coil wire path 71 of the first inductor section being not symmetric about the center line Q. In addition, above and below the element body center plane M, the first internal electrodes C51 and the second internal electrodes C52 are symmetric with respect to the center line Q.

Furthermore, when viewed in the layering direction, the first internal electrodes C51 and the second internal electrodes C52 are symmetric with respect to the element body center O (the center of the element body). When viewed in the layering direction, the first coil wire path portion 71 of the first inductor section 30A and the first coil wire path portion 74 of the second inductor section 30B are disposed to be symmetric with respect to the element body center O. Additionally, when viewed in the layering direction, the second coil wire path portion 72 of the first inductor section 30A and the second coil wire path portion 73 of the second inductor section 30B are disposed to be symmetric with respect to the element body center O.

Alternatively, the first coil wire path portion 71 of the first inductor section 30A and the second coil wire path portion 73 of the second inductor section 30B may be disposed to be symmetric with respect to the element body center O when viewed in the layering direction, while the second coil wire path portion 72 of the first inductor section 30A and the first coil wire path portion 74 of the second inductor section 30B may also be disposed to be symmetric about the center O when viewed in the layering direction.

This structure can eliminate the mounting directivity of the LC composite component 1. This can reduce the alignment work of the mounting direction of the LC composite component when being mounted onto the circuit board. Furthermore, the aforementioned structure enables the LC composite component 1 to be employed as an LC filter having constant properties because the properties of the LC composite component 1 do not vary depending on the mounting direction.

The first inductor section 30A is preferably configured such that the first coil wire path portion 71 and the second coil wire path portion 72 should be drawn out to the first element body side face 10c, to which the first internal electrodes C51 are also drawn out, so as to be adjacent to the first internal electrodes C51 in the layering direction. Alternatively, the second inductor section 30B is preferably configured such that the first coil wire path portion 74 and the second coil wire path portion 73 should be drawn out to the second element body side face 10d, to which the second internal electrodes C52 are also drawn out, so as to be adjacent to the second internal electrodes C52 in the layering direction.

This structure allows the inductor sections and the capacitor section to be adjacent to each other with the same polarity. For example, with the capacitor section and the inductor sections being adjacent to each other with different polarities, there would develop capacitance between the inductor sections and the capacitor section, resulting in the inductor sections and the capacitor section being coupled to each other. This would cause the noise attenuation performance to be degraded, leading to the possibility of insufficient removal of noise components. The aforementioned structure allows the inductor sections and the capacitor section to be adjacent to each other with the same polarity, thereby providing improved noise attenuation performance and thus enabling noise components to be removed.

As described above, the LC composite component 1 is configured such that the first coil wire path portions 71 and 74 and the second coil wire path portions 72 and 73 are adjacent to each other via the insulator layers 31 and 33, respectively. This allows a magnetic flux established in the first coil wire path portions 71 and 74 and the second coil wire path portions 72 and 73 to be developed around the mutual coil wire paths, thus providing increased inductance. The LC composite component 1 is also configured such that the inductor section 30A (30B) and the capacitor section 50A can be adjacent to each other with the same polarity because the first internal electrodes C51 or the second internal electrodes C52 are not sandwiched between the first coil wire path portion 71 and the second coil wire path portion 72.

The aforementioned LC composite component 1 is manufactured in the manufacturing method below. First, a dielectric material such as unbaked barium titanate (BaTiO₃) or a magnetic substance such as ferrite is used to form a green sheet which is to be an insulator layer. Then, on the surface of the green sheet, electrically conductive paste containing conductor powder or the like is printed in a predetermined pattern. This electrically conductive paste is dried, thereby providing a desired electrically conductive pattern on the surface of the insulator layers 31, 32, 51, 52, 51, 52, 33, and 34.

Furthermore, the green sheets to be the insulator layers 17, 18, and 19 are formed of a dielectric material such as unbaked barium titanate (BaTiO₃), a magnetic substance material such as ferrite, or other insulator materials. The green sheets are stacked one on another to provide a layered structure which includes the insulator layer 17, the insulator layer 18, the insulator layer 31, the insulator layer 32, the insulator layer 51, the insulator layer 52, the insulator layer 51, the insulator layer 52, the insulator layer 33, the insulator layer 34, and the insulator layer 19, in that order from the first element body principal face 10a toward the second element body principal face 10b (see FIG. 2 to FIG. 4).

The layered structure of the element body 10 is formed in the shape of sheets which include a plurality of element bodies 10 having been partitioned. Then, the sheets that contain the plurality of element bodies 10 are cut in a predetermined size so as to provide individual layered structures each corresponding to the element body 10.

Subsequently, the resulting layered structure of the element bodies 10 is processed to remove the binder and baked, thereby providing a layered structure. In this manner, the insulator layers included in the layered structure are baked and the conductor patterns are sintered, thus providing the element body 10.

The element body 10 is configured such that after electrically conductive paste is applied to the predetermined positions of the first element body side face 10c, the second element body side face 10d, the first element body end face 10e, and the second element body end face 10f, the applied electrically conductive paste is baked, for example, at about 800° C., thereby forming the terminal portions 11a, 12a, 13a, 21a, 22a, 23a, 11b, 12b, 13b, 21b, 22b, and 23b as well as the external conductor portions 11c, 12c, 13c, 21d, 22d, and 23d.

Subsequently, as required, the terminal portions 11a, 12a, 13a, 21a, 22a, 23a, 11b, 12b, 13b, 21b, 22b, and 23b and the external conductor portions 11c, 12c, 13c, 21d, 22d, and 23d are electroplated (for example, with copper, nickel, and tin), thereby completing the LC composite component 1 shown in FIG. 1. LC composite components according to other embodiments, to be described later, will also be manufactured in the same manner.

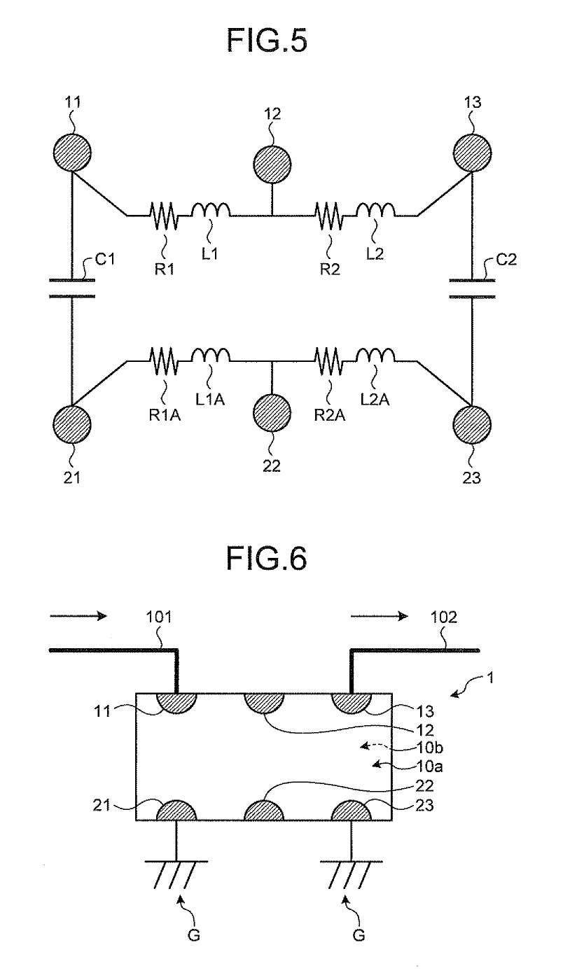

FIG. 5 is an explanatory view illustrating an equivalent circuit of the LC composite component according to the first embodiment. As described above, the external conductor portion 11c is an electrical conductor for electrically connecting to the extraction electrode portions 111, 511, and 511. The external conductor portion 12c is an electrical conductor for electrically connecting to the extraction electrode portions 112 and 212. The external conductor portion 13c is an electrical conductor for electrically connecting to the extraction electrode portions 213, 513, and 513.

The external conductor portion 21d is an electrical conductor for electrically connecting to the electrode portions 521, 521, and 321. The external conductor portion 22d is an electrical conductor for electrically connecting to the extraction electrode portions 322 and 422. The external conductor portion 23d is an electrical conductor for electrically connecting to the extraction electrode portions 523, 523, and 423. Accordingly, the external conductors 11, 12, 13, 21, 22, and 23 connect to the inductor section 30A, the inductor section 30B, and the capacitor section 50A, thereby forming the equivalent circuit shown in FIG. 5 within the LC composite component 1.

The equivalent circuit shown in FIG. 5 has the external conductors 11, 12, 13, 21, 22, and 23, an inductor L1, an inductor internal resistor R1, an inductor L2, an inductor internal resistor R2, a capacitor C1, a capacitor C2, an inductor L1A, an inductor internal resistor R1A, an inductor L2A, and an inductor internal resistor R2A.

The inductor L1 and the inductor internal resistor R1 are formed by the first coil wire path portion 71 of the aforementioned first inductor section 30A. In the equivalent circuit, the inductor L1 and the inductor internal resistor R1 are connected in series between the external conductors 11 and 12. Furthermore, the inductor L2 and the inductor internal resistor R2 are formed by the second coil wire path portion 72 of the first inductor section 30A. In the equivalent circuit, the inductor L2 and the inductor internal resistor R2 are connected in series between the external conductors 12 and 13.

The capacitor C1 is formed by the principal face electrode portions C511 and C521 of the aforementioned capacitor section 50A. The capacitor C1 is connected between the external conductors 11 and 21. Furthermore, the capacitor C2 is formed by the principal face electrode portions C513 and C523 of the capacitor section 50A. The capacitor C2 is connected between the external conductors 13 and 23.

The inductor L1A and the inductor internal resistor R1A are formed by the second coil wire path portion 73 of the aforementioned second inductor section 30B. In the equivalent circuit, the inductor L1A and the inductor internal resistor R1A are connected in series between the external conductors 21 and 22. Furthermore, the inductor L2A and the inductor internal resistor R2A are formed by the first coil wire path portion 74 of the second inductor section 30B. In the equivalent circuit, the inductor L2A and the inductor internal resistor R2A are connected in series between the'external conductors 22 and 23.

FIG. 6 is an explanatory view illustrating an example of connection between the LC composite component according to the first embodiment and signal lines. In the example, the LC composite component 1 is shown with the second element body principal face 10b being opposed to a circuit board, in which the LC composite component 1 is connected to the signal lines 101 and 102. At least the two external conductors 11 and 13 other than the external conductor 12 connecting between the first coil wire path portion 71 and the second coil wire path portion 72 which are included in the first inductor section 30A are electrically connected to the signal lines 101 and 102 of the circuit board, respectively. Furthermore, at least two external conductors 21 and 23 connected to the second internal electrodes C52 of the capacitor section are electrically connected to a GND line G of the circuit board.

As shown in FIG. 6, for example, the external conductor 11 and the external conductor 13 are connected to the signal line 101 and the signal line 102, respectively. Accordingly, the external conductor 11 serves as a terminal electrode for signal input (signal input terminal electrode) into which signals are input. On the other hand, the external conductor 13 serves as a terminal electrode for signal output (signal output terminal electrode) from which signals are output. At least the external conductor 21 and the external conductor 23 are connected to the GND line G and grounded. Accordingly, the external conductors 21 and 23 serve as a terminal electrode for GND (GND terminal electrode). The external conductor 12 serves as what is called an external connection conductor (coupling conductor) which is not directly connected to the circuit board.

The external conductor 12 connects the first coil wire path portion 71 and the second coil wire path portion 72 of the inductor section 30A, but is not connected to the circuit board. Note that the external conductor 22 may also be employed as what is called an external connection conductor that is not directly connected to the circuit board, or alternatively as a GND terminal electrode which is connected to the GND line G and grounded. This causes the inductors L1A and L2A not to operate in the equivalent circuit shown in FIG. 5, but allows the LC composite component 1 to operate as what is called a π-type noise filter (π-type circuit).

As a second mounting structure, the LC composite component 1 may be configured such that with the second element body principal face 10b opposed to the circuit board, of the external conductors 11, 12, 13, 21, 22, and 23, the external conductor 23 should be connected to the signal line 101, while the external conductor 21 should be connected to the signal line 102. In this case, the external conductor 23 serves as a signal input terminal electrode into which a signal is input. On the other hand, the external conductor 21 serves as a signal output terminal electrode from which a signal is output. The external conductor 22 serves as what is called an external connection conductor that is not directly connected to the circuit board.

In the second mounting structure, at least the external conductor 11 and the external conductor 13 are connected to the GND line G and grounded. Accordingly, the external conductors 11 and 13 serve as a GND terminal electrode. Note that the external conductor 12 may also be employed as what is called an external connection conductor that is not directly connected to the circuit board or alternatively as a GND terminal electrode which is connected to the GND line G and grounded. This causes the inductors L1 and L2 not to operate in the equivalent circuit shown in FIG. 5, but allows the LC composite component 1 to operate as what is called a π-type noise filter.

As a third mounting structure, the LC composite component 1 may be configured such that with the first element body principal face 10a opposed to the circuit board, of the external conductors 11, 12, 13, 21, 22, and 23, the external conductor 13 should be connected to the signal line 101, while the external conductor 11 should be connected to the signal line 102. In this case, the external conductor 13 serves as a signal input terminal electrode into which a signal is input. Furthermore, the external conductor 11 serves as a signal output terminal electrode from which a signal is output. Furthermore, the external conductor 12 serves as what is called an external connection conductor that is not directly connected to the circuit board.

In the third mounting structure, at least the external conductor 21 and the external conductor 23 are connected to the GND line G and grounded. Accordingly, the external conductors 21 and 23 serve as a GND terminal electrode. Note that the external conductor 22 may also be employed as what is called an external connection conductor that is not directly connected to the circuit board or alternatively as a GND terminal electrode which is connected to the GND line G and grounded. This causes the inductors L1A and L2A in the equivalent circuit shown in FIG. 5 not to operate, but allows the LC composite component 1 to operate as what is called a π-type noise filter.

As a fourth mounting structure, the LC composite component 1 may be configured such that with the first element body principal face 10a opposed to the circuit board, of the external conductors 11, 12, 13, 21, 22, and 23, the external conductor 21 should be connected to the signal line 101, while the external conductor 23 should be connected to the signal line 102. In this case, the external conductor 21 serves as a signal input terminal electrode into which a signal is input. On the other hand, the external conductor 23 serves as a signal output terminal electrode from which a signal is output. Furthermore, the external conductor 22 serves as what is called an external connection conductor that is not directly connected to the circuit board.

In the fourth mounting structure, at least the external conductor 11 and the external conductor 13 are connected to the GND line G and grounded. Accordingly, the external conductors 11 and 13 serve as a GND terminal electrode. Note that the external conductor 12 may also be employed as what is called an external connection conductor that is not directly connected to the circuit board, or alternatively as a GND terminal electrode which is connected to the GND line G and grounded. This causes the inductors L1 and L2 in the equivalent circuit shown in FIG. 5 not to operate, but allows the LC composite component 1 to operate as what is called a π-type noise filter.

As described above, the LC composite component 1 is capable of operating as an equivalent π-type noise filter when seen from the signal lines 101 and 102 even when any one of the first element body principal face 10a and the second element body principal face 10b is opposed to the circuit board. Furthermore, when viewed in the layering direction, the LC composite component 1 is capable of operating as an equivalent π-type noise filter when seen from the signal lines 101 and 102 even when the LC composite component 1 is rotated by 180° about the element body center O within the circuit board plane. This can reduce the alignment work of the mounting direction of the LC composite component 1 when being mounted onto the circuit board. Furthermore, the aforementioned structure enables the LC composite component 1 to be employed as an LC filter having constant properties because the properties of the LC composite component 1 do not vary depending on the mounting direction.

### Second Embodiment

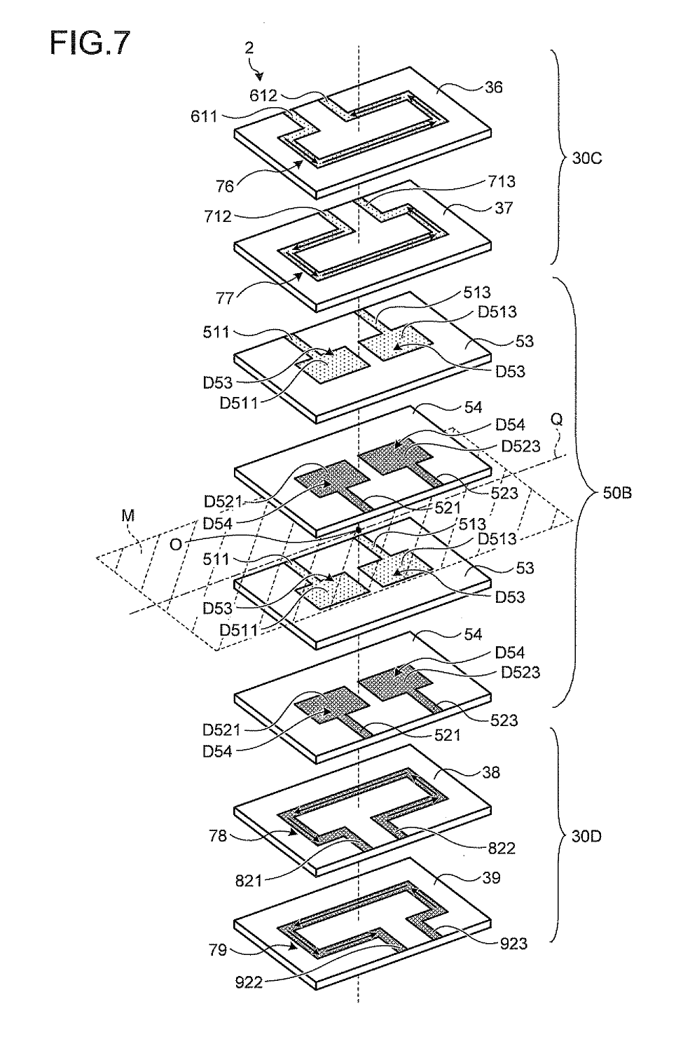

FIG. 7 is an exploded perspective view illustrating the main portion of the element body of an LC composite component according to a second embodiment. FIG. 7 illustrates the element body 10 which is decomposed in the order of layering except for the aforementioned insulator layers 17, 18, and 19. The LC composite component 2 according to this embodiment is configured such that when viewed in the layering direction, first coil wire path portions 76 and 79 and second coil wire path portions 77 and 78, to be described later, are wound around at least one of first principal face electrode portions D511 and D513 of first internal electrodes D53 adjacent to a first inductor section 30C and second principal face electrode portions D521 and D523 of second internal electrodes D54 adjacent to a second inductor section 30D.

In the descriptions below, the same components as those described in relation to the first embodiment will be denoted by the same reference signs without repeating the same explanations.

The LC composite component 2 includes a capacitor section 50B, the first inductor section 30C, and the second inductor section 30D. As shown in FIG. 7, the LC composite component 2 is configured such that the capacitor section and the inductor sections are alternately stacked in layers in the order of the first inductor section 30C, the capacitor section 50B, and the second inductor section 30D. The LC composite component 2 is also configured such that the first inductor section 30C and the second inductor section 30D are symmetric with respect to the capacitor section 50B in the layering direction. This allows the first inductor section 30C and the second inductor section 30D to be disposed close to the first element body principal face 10a and the second element body principal face 10b of the LC composite component 2.

For example, with respect to the element body center O, the first internal electrodes D53 and the second internal electrodes D54 of the capacitor section 50B, to be described later, are disposed at the same position and the same distance. Furthermore, the first coil wire path portion 76 of the first inductor section 30C and the first coil wire path portion 79 of the second inductor section 30D, to be described later, are disposed at the same position and the same distance with respect to the element body center O. Furthermore, the second coil wire path portion 77 of the first inductor section 30C and the second coil wire path portion 78 of the second inductor section 30D are disposed at the same position and the same distance with respect to the element body center O.

The first inductor section 30C has insulator layers 36 and 37, electrically conductive extraction electrode portions 611 and 612 formed on the insulator layer 36, electrically conductive extraction electrode portions 712 and 713 formed on the insulator layer 37, the electrically conductive first coil wire path portion 76 formed on the insulator layer 36, and the second coil wire path portion 77 formed on the insulator layer 37.

The second inductor section 30D has insulator layers 38 and 39, electrically conductive extraction electrode portions 821 and 822 formed on the insulator layer 38, electrically conductive extraction electrode portions 922 and 923 formed on the insulator layer 39, the electrically conductive second coil wire path portion 78 formed on the insulator layer 38, and the first coil wire path portion 79 formed on the insulator layer 39.

The relation between the extraction electrode portions 611, 612, 712, 713, 821, 822, 922, and 923, which are formed on the surface of any one of the insulator layers 36, 37, 38, and 39, and the first coil wire path portions 76 and 79 as well as the second coil wire path portions 77 and 78 is the same as the relation between the extraction electrode portions 111, 112, 212, 213, 321, 322, 422, and 423 and the coil wire path portions 71 and 74 as well as the second coil wire path portions 72 and 73, as described in relation to the first embodiment (see FIG. 2).

The first inductor section 30C is configured such that the first coil wire path portion 76 and the second coil wire path portion 77 are connected to the external conductor 12 shown in FIG. 1. This causes the first coil wire path portion 76 and the second coil wire path portion 77 to serve as a spiral coil which is wound in a helical fashion along the layering direction.

Furthermore, the second inductor section 30D is configured such that the first coil wire path portion 79 and the second coil wire path portion 78 are connected to the external conductor 22 shown in FIG. 1. This causes the first coil wire path portion 79 and the second coil wire path portion 78 to serve as a spiral coil which is wound in a helical fashion along the layering direction.

The capacitor section 50B includes the first internal electrodes D53 formed on the surface of an insulator layer 53 and the second internal electrodes D54 formed on the surface of the insulator layer 54. The first internal electrodes D53 and the second internal electrodes D54 are also opposed to each other in the layering direction. The first internal electrodes D53 each have the electrically conductive extraction electrode portion 511 or 513 which is formed on the surface of the insulator layer 53, and the electrically conductive first principal face electrode portion D511 or D513 which is also formed on the surface of the insulator layer 53. The second internal electrodes D54 each have the electrically conductive extraction electrode portion 521 or 523 which is formed on the surface of the insulator layer 54 and the electrically conductive second principal face electrode portion D521 or D523 which is also formed on the surface of the insulator layer 54.

The extraction electrode portions 511 and 513 of the first internal electrodes D53 are drawn out to the first element body side face 10c and then connected to the external conductors 11 and 13 of the first external conductor group 15 shown in FIG. 1. Furthermore, the extraction electrode portions 521 and 523 of the second internal electrodes D54 are drawn out to the second element body side face 10d and then connected to the external conductors 21 and 23 of the second external conductor group 25 shown in FIG. 1.

The first inductor section 30C and the second inductor section 30D are separately disposed above and below the element body center O in the layering direction. Furthermore, the first internal electrodes D53 and the second internal electrodes D54 are disposed at the same position and the same distance with respect to the element body center O.

The LC composite component 2 is also configured such that the first coil wire path portion 76 of the first inductor section 30C and the first coil wire path portion 79 of the second inductor section 30D are disposed at the same position and the same distance with respect to the element body center O. The LC composite component 2 is also configured such that the second coil wire path portion 77 of the first inductor section 30C and the second coil wire path portion 78 of the second inductor section 30D are disposed at the same position and the same distance.

The LC composite component 2 is further configured such that when viewed in the layering direction, the first internal electrodes D53 and the second internal electrodes D54 are symmetric with respect to the element body center O. The LC composite component 2 is also preferably configured such that the first coil wire path portion 76 of the first inductor section 30C and the first coil wire path portion 79 of the second inductor section 30D should be disposed to be symmetric with respect to the element body center O when viewed in the layering direction, while the second coil wire path portion 77 of the first inductor section 30C and the second coil wire path portion 78 of the second inductor section 30D should also be disposed to be symmetric about the center O when viewed in the layering direction.

This structure can eliminate the mounting directivity of the LC composite component 2. This can reduce the alignment work of the mounting direction of the LC composite component 2 when the LC composite component 2 is being mounted onto the circuit board. Furthermore, the aforementioned structure enables the LC composite component 2 to be employed as an LC filter having constant properties because the properties thereof do not vary depending on the mounting direction.

When viewed in the layering direction, the first coil wire path portions 76 and 79 and the second coil wire path portions 77 and 78, which are included in the first inductor section 30C or the second inductor section 30D as described above, are wound around at least one of the first principal face electrode portions D511 and D513 of the first internal electrodes D53 adjacent to the first inductor section 30C and the second principal face electrode portions D521 and D523 of the second internal electrodes D54 adjacent to the second inductor section 30D.

This allows the first coil wire path portions 76 and 79 and the second coil wire path portions 77 and 78, which are included in the first inductor section 30C or the second inductor section 30D, are wound around on the surface of the insulator layers 36, 37, 38, and 39, avoiding the region opposed to the principal face electrode portions D511, D513, D521, and D523 of the capacitor section 50B in the layering direction.

Furthermore, the regions of the insulator layers 36, 37, 38, and 39 which are opposed in the layering direction to the principal face electrode portions D511, D513, D521, and D523 are to be defined as the regions through which the first coil wire path portions 76 and 79 and the second coil wire path portions 77 and 78 will not pass. As a result, the principal face electrode portions D511, D513, D521, and D523 less overlap with the first coil wire path portions 76 and 79 and the second coil wire path portions 77 and 78 in the layering direction. This can reduce the capacitance between the principal face electrode portions D511, D513, D521, and D523 and the first coil wire path portions 76 and 79 as well as the second coil wire path portions 77 and 78.

For example, with the principal face electrode portions of the capacitor section overlapping the coil wire path portions of the inductor sections in the layering direction, capacitance is developed between the principal face electrode portions of the capacitor section and the coil wire path portions of the inductor sections, causing the capacitor section and the inductor sections to be coupled to each other. When a high-frequency noise component is input to the LC composite component under this condition, the capacitor section and the inductor sections will behave only as one electrical conductor in relation to the high-frequency noise component. This may cause a signal to pass through the LC composite component with the high-frequency noise component not attenuated.

For example, in general, the first coil wire path portions 76 and 79 and the second coil wire path portions 77 and 78 are reduced in width as compared with the principal face electrode portions D511, D513, D521, and D523. As described above, with the capacitor section 50B being coupled to the inductor section 30C or the second inductor section 30D, the noise component would sufficiently flow not through the first coil wire path portions 76 and 79 or the second coil wire path portions 77 and 78, which are reduced in width and wound around, but through the principal face electrode portions D511, D513, D521, and D523, which have an increased electrode width. This may cause the inductor section 30C or the second inductor section 30D to sufficiently remove noise.

For example, when the coil wire path is formed as a meandering conductor pattern, the conductor pattern meanders, so that the principal face electrode portions of the capacitor section and the coil wire path portions of the inductor sections should probably overlap each other in the layering direction.

In contrast to this, since the LC composite component 2 is configured such that the first inductor section 30C and the second inductor section 30D are formed in a spiral coil, the first coil wire path portions 76 and 79 and the second coil wire path portions 77 and 78 can be readily disposed so as to avoid the principal face electrode portions D511, D513, D521, and D523. Accordingly, the LC composite component 2 is reduced in the capacitance between the principal face electrode portions D511, D513, D521, and D523 and the first coil wire path portions 76 and 79 as well as the second coil wire path portions 77 and 78. As a result, the LC composite component 2 can attenuate the high-frequency noise component.

The LC composite component 2 is configured such that the principal face electrode portions D511, D513, D521, and D523 are elongated in the direction of the longer sides of the element body 10. This tends to prevent the coil wire path portions 76, 77, 78, and 79 and the principal face electrode portions D511, D513, D521, and D523 from overlapping each other when viewed in the layering direction.

### First Modified Example

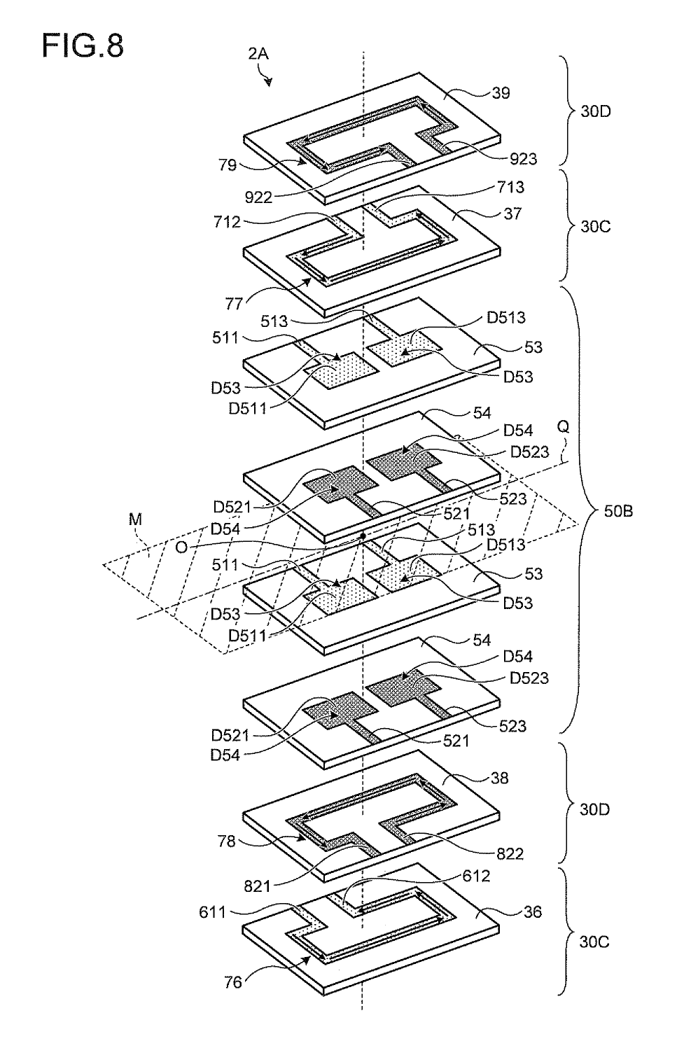

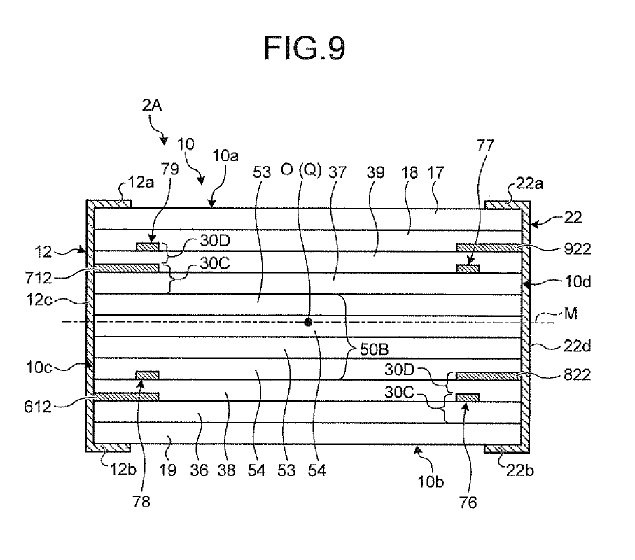

FIG. 8 is an exploded perspective view illustrating the main portion of the element body of an LC composite component according to a first modified example of the second embodiment. FIG. 9 is a cross-sectional view illustrating the element body of the LC composite component according to the first modified example of the second embodiment. FIG. 8 illustrates the element body 10 which is decomposed in the layering order except for the aforementioned insulator layers 17, 18, and 19. FIG. 9 is a cross-sectional view taken along line A-A of FIG. 1. In the descriptions below, the same components as those described in relation to the aforementioned embodiments will be denoted by the same reference signs without repeating the same explanations. The LC composite component 2A according to this modified example is configured such that the position of the first coil wire path portion 76 of the first inductor section 30C is changed to the position of the first coil wire path portion 79 of the second inductor section 30D in the LC composite component 2.

The first inductor sections 30C are configured such that the first coil wire path portion 76 and the second coil wire path portion 77 are connected to the external conductor 12 shown in FIG. 1. This causes the first coil wire path portion 76 and the second coil wire path portion 77 to serve as a spiral coil which is wound in a helical fashion along the layering direction.

Furthermore, the second inductor sections 30D are configured such that the first coil wire path portion 79 and the second coil wire path portion 78 are connected to the external conductor 22 shown in FIG. 1. This causes the first coil wire path portion 79 and the second coil wire path portion 78 to serve as a spiral coil which is wound in a helical fashion along the layering direction.

The first inductor sections 30C and the second inductor sections 30D are divided above and below the capacitor section 50B in the layering direction. The intervention of the capacitor section 50B causes the length of the external conductor 12 (22) connecting between the first coil wire path portion 76 (79) and the second coil wire path portion 77 (78) to be greater than that of the LC composite component 2 shown in FIG. 7. Accordingly, the LC composite component 2A shown in FIG. 9 has a greater length of the external conductor 12 connecting between the first coil wire path portion 76 and the second coil wire path portion 77 than that of the aforementioned LC composite component 2. Likewise, the length of the external conductor 22 connecting between the first coil wire path portion 79 and the second coil wire path portion 78 is also increased. Since this causes an increase in the resistance of the external conductors 12c and 22d shown in FIG. 1, the inductor internal resistors R1, R2, R1A, and R2A (see FIG. 5) can be increased. As a result, the LC composite component 2A can be increased in impedance.

### Second Modified Example

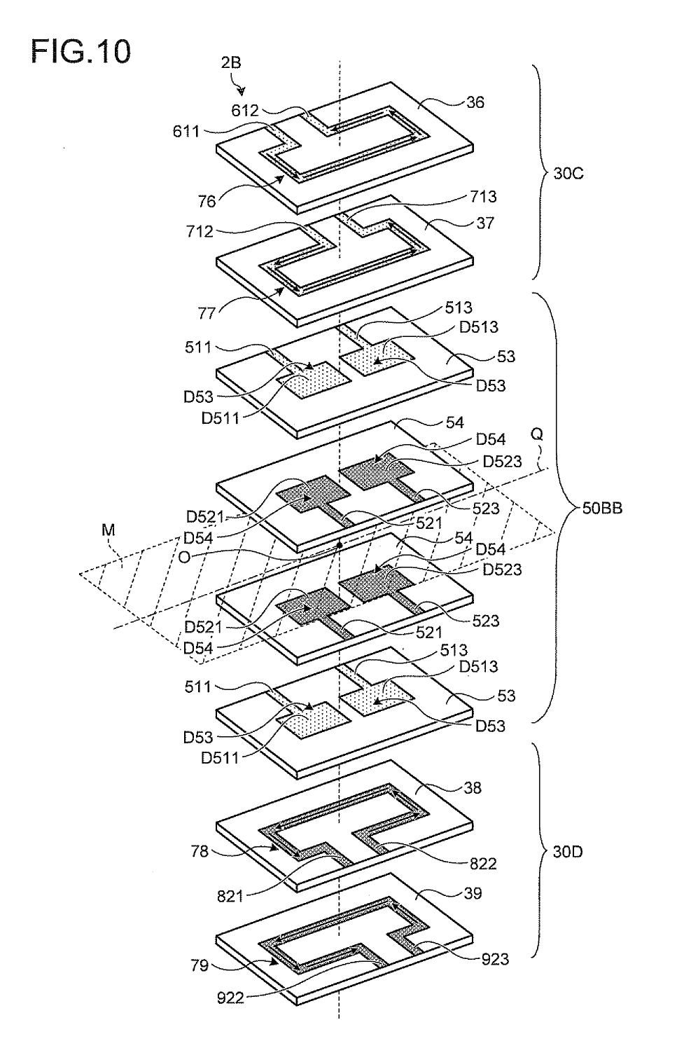

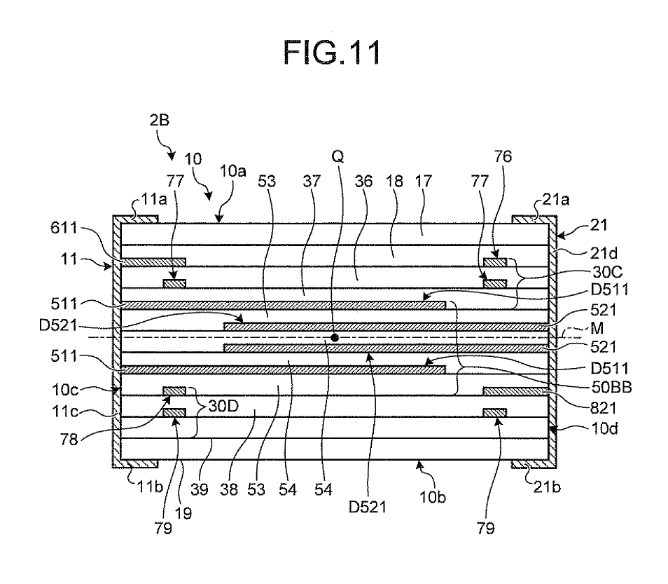

FIG. 10 is an exploded perspective view illustrating the main portion of the element body of an LC composite component according to a second modified example of the second embodiment. FIG. 11 is a cross-sectional view illustrating the element body of the LC composite component according to the second modified example of the second embodiment. FIG. 10 illustrates the element body 10 which is decomposed in the layering order except for the aforementioned insulator layers 17, 18, and 19. FIG. 11 is a cross-sectional view taken along line B-B of FIG. 1. In the descriptions below, the same components as those described in relation to the aforementioned embodiments will be denoted by the same reference signs without repeating the same explanations. The LC composite component 2B according to this modified example is configured such that the first internal electrodes D53 as well as the second internal electrodes D54 are disposed at the same position and the same distance with respect to the element body center O.

Like the LC composite component 2 shown in FIG. 7, the LC composite component 2B includes the first inductor section 30C and the second inductor section 30D. As shown in FIG. 10, the LC composite component 2B is configured such that the capacitor section and the inductor sections are alternately stacked in layers in the order of the first inductor section 30C, the capacitor section 50BB, and the second inductor section 30D. The LC composite component 2B is also configured such that the first inductor section 30C and the second inductor section 30D are symmetric with respect to the capacitor section 50BB in the layering direction. This allows the first inductor section 30C and the second inductor section 30C to be disposed close to the first element body principal face 10a and the second element body principal face 10b of the LC composite component 2B.

As described above, the LC composite component 2B is configured such that the first inductor section 30C and the second inductor section 30D are separately disposed above and below the element body center plane M in the layering direction as shown in FIGS. 10 and 11. Furthermore, the first internal electrodes D53 as well as the second internal electrodes D54 are disposed at the same position and the same distance with respect to the element body center O.

Furthermore, the LC composite component 2B is configured such that with respect to the element body center O, the first coil wire path portion 76 of the first inductor section 30C and the first coil wire path portion 79 of the second inductor section 30D are disposed at the same position and the same distance, while the second coil wire path portion 77 of the first inductor section 30C and the second coil wire path portion 78 of the second inductor section 30D are also disposed at the same position and the same distance.

In other words, the first coil wire path portion 76 of the first inductor section 30C and either the first coil wire path portion 79 or the second coil wire path portion 78 of the second inductor section 30D are symmetric with respect to the center line Q passing through the intermediate position on the element body center plane M between the first element body side face 10c and the second element body side face 10d. Accordingly, the first coil wire path portion 76 can have an electrically conductive pattern which when rotated about the center line Q, overlaps the electrically conductive pattern of the first coil wire path portion 79 or the second coil wire path portion 78, when viewed in the layering direction. In this embodiment, the first coil wire path portion 76 and the second coil wire path portion 78 are symmetric with respect to the center line Q.

Furthermore, the second coil wire path portion 77 of the first inductor section 30C and one of the first coil wire path portion 79 and the second coil wire path portion 78 of the second inductor section 30D are symmetric with respect to the center line Q, the one and the second coil wire path portion 76 of the first inductor section 30C being not symmetric about the center line Q. The second coil wire path portion 77 has an electrically conductive pattern which when rotated about the center line Q, overlaps that of the first coil wire path portion 79 or the second coil wire path portion 78.

Furthermore, the capacitor section 50B of the aforementioned LC composite component 2 (see FIG. 7) is configured such that the first internal electrodes D53 and the second internal electrodes D54 are symmetric with respect to the center line Q above and below the element body center plane M. In contrast to this, the capacitor section 50BB of the LC composite component 2B according to the second modified example is configured such that the first internal electrodes D53 and the second internal electrodes D54 are symmetric with respect to the element body center plane M above and below the element body center plane M.

The LC composite component 2B is configured such that the first internal electrodes D53 and the second internal electrodes D54 are symmetric with respect to the element body center O (the center of the element body) when viewed in the layering direction. Furthermore, the LC composite component 2B is configured such that the first coil wire path portion 76 of the first inductor section 30C and the first coil wire path portion 79 of the second inductor section 30D are disposed to be symmetric with respect to the element body center O when viewed in the layering direction. Furthermore, the LC composite component 2B is configured such that the second coil wire path portion 77 of the first inductor section 30C and the second coil wire path portion 78 of the second inductor section 30D are disposed to be symmetric about the center when viewed in the layering direction.

Alternatively, the LC composite component 2B may be configured such that the first coil wire path portion 76 of the first inductor section 30C and the second coil wire path portion 78 of the second inductor section 30D should be disposed to be symmetric with respect to the element body center O when viewed in the layering direction, while the second coil wire path portion 77 of the first inductor section 30C and the first coil wire path portion 79 of the second inductor section 30D should be disposed to be symmetric with respect to the center O when viewed in the layering direction.

This structure can eliminate the mounting directivity of the LC composite component. This can reduce the alignment work of the mounting direction of the LC composite component 2B when the LC composite component 2B is mounted onto the circuit board. Furthermore, the aforementioned structure enables the LC composite component 2B to be employed as an LC filter having constant properties because the properties of the LC composite component 2B do not vary depending on the mounting direction.

### Third Modified Example

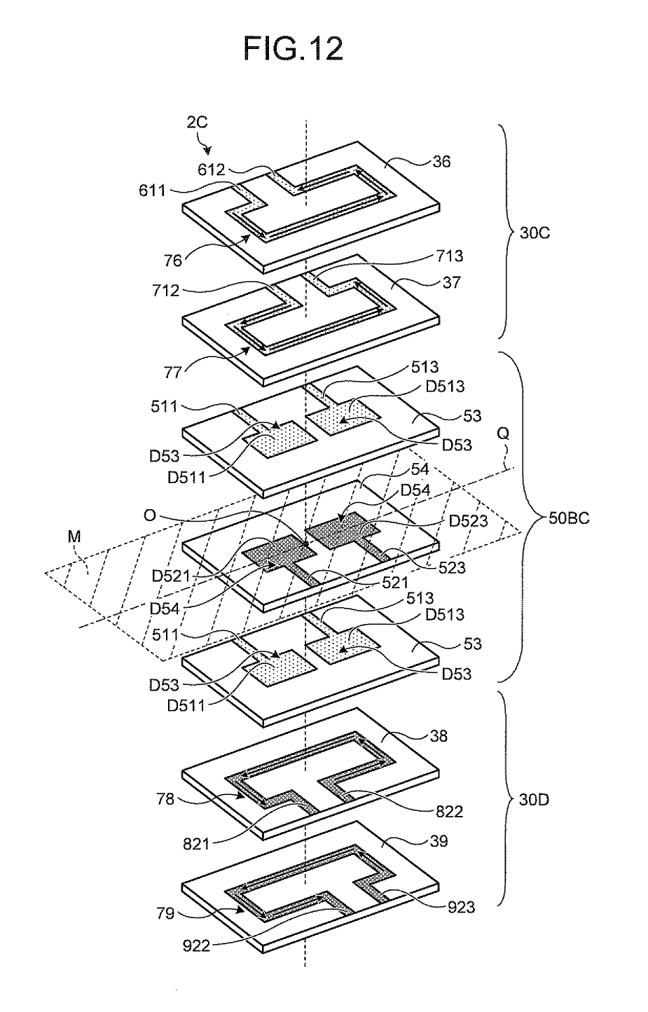

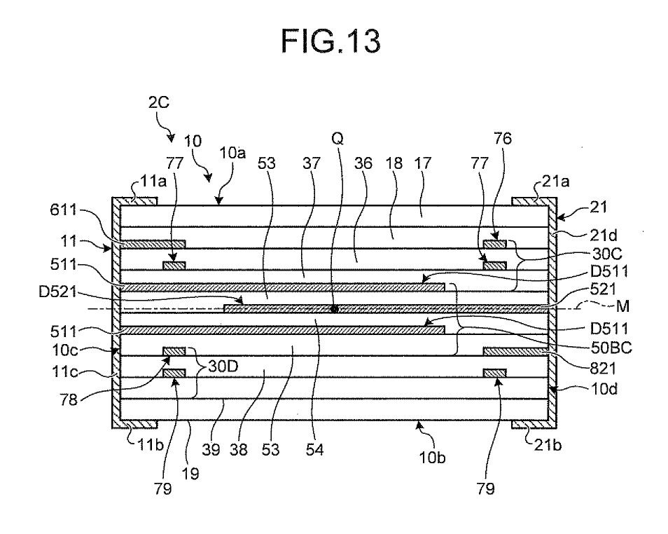

FIG. 12 is an exploded perspective view illustrating the main portion of the element body of an LC composite component according to a third modified example of the second embodiment. FIG. 13 is a cross-sectional view illustrating the element body of LC composite component according to the third modified example of the second embodiment. FIG. 12 illustrates the element body 10 which is decomposed in the layering order except for the aforementioned insulator layers 17, 18, and 19. FIG. 13 is a cross-sectional view taken along line B-B of FIG. 1. In the descriptions below, the same components as those described in relation to the aforementioned embodiments will be denoted by the same reference signs without repeating the same explanations. The LC composite component 2C according to this modified example is configured such that the first internal electrodes D53 are disposed at the same position and the same distance with respect to the element body center O.

Like the LC composite component 2 shown in FIG. 7, the LC composite component 2C includes the first inductor section 30C and the second inductor section 30D. As shown in FIG. 12, the LC composite component 2C is configured such that the capacitor section and the inductor sections are alternately stacked in layers in the order of the first inductor section 30C, the capacitor section 50BC, and the second inductor section 30D. The LC composite component 2C is also configured such that the first inductor section 30C and the second inductor section 30D are symmetric with respect to the capacitor section 50BC in the layering direction. This allows the first inductor section 30C and the second inductor section 30D to be disposed close to the first element body principal face 10a and the second element body principal face 10b of the LC composite component 2C.

As described above, the LC composite component 2C is configured such that the first inductor section 30C and the second inductor section 30D are separately disposed above and below the element body center plane M in the layering direction as shown in FIGS. 12 and 13. Furthermore, the element body center plane M including the element body center O lies within the second internal electrodes D54. The first internal electrodes D53 are disposed at the same position and the same distance with respect to the element body center O.

The capacitor section 50BC may further include the second internal electrodes D54, so that the second internal electrodes D54, the first internal electrodes D53, the second internal electrodes D54, the first internal electrodes D53, and the second internal electrodes D54 are stacked in layers in that order from the first element body principal face 10a toward the second element body principal face 10b. This structure allows the capacitor section 50BC to be configured such that the second internal electrodes D54 near the first element body principal face 10a are opposed to the first internal electrodes D53 near the first element body principal face 10a, while the second internal electrodes D54 near the second element body principal face 10b are opposed to the first internal electrodes D53 near the second element body principal face 10b. In this case, the second internal electrodes D54 are also disposed at the same position and the same distance with respect to the element body center O except for the second internal electrodes D54 including the element body center plane M.

As another modified example, the element body center plane M including the element body center O may be disposed within the first internal electrodes D53, and the second internal electrodes D54 may be disposed at the same position and the same distance with respect to the element body center O. In this case, the capacitor section may further include the first internal electrodes D53, so that the first internal electrodes D53, the second internal electrodes D54, the first internal electrodes D53, the second internal electrodes D54, and the first internal electrodes D53 are stacked in layers in that order from the first element body principal face 10a toward the second element body principal face 10b. This structure allows the capacitor section to be configured such that the first internal electrodes D53 near the first element body principal face 10a are opposed to the second internal electrodes D54 near the first element body principal face 10a, while the first internal electrodes D53 near the second element body principal face 10b are opposed to the second internal electrodes D54 near the second element body principal face 10b. Furthermore, the first internal electrodes D53 are disposed at the same position and the same distance with respect to the element body center O except for the first internal electrodes D53 including the element body center plane M.

The LC composite component 2C is also configured such that with respect to the element body center O, the first coil wire path portion 76 of the first inductor section 30C and the first coil wire path portion 79 of the second inductor section 30D are disposed at the same position and the same distance as well as the second coil wire path portion 77 of the first inductor section 30C and the second coil wire path portion 78 of the second inductor section 30D are disposed at the same position and the same distance.

In other words, the first coil wire path portion 76 of the first inductor section 30C and either the first coil wire path portion 79 or the second coil wire path portion 78 of the second inductor section 30D are symmetric with respect to the center line Q passing through the intermediate position on the element body center plane M between the first element body side face 10c and the second element body side face 10d. Accordingly, the first coil wire path portion 76 can have an electrically conductive pattern which when rotated about the center line Q, overlaps the electrically conductive pattern of the first coil wire path portion 79 or the second coil wire path portion 78 when viewed in the layering direction. In this embodiment, the first coil wire path portion 76 and the second coil wire path portion 78 are symmetric with respect to the center line Q.

Furthermore, the second coil wire path portion 77 of the first inductor section 30C and one of the first coil wire path portion 79 and the second coil wire path portion 78 of the second inductor section 30D are symmetric with respect to the center line Q, the one and the first coil wire path portion 76 of the first inductor section 30C being not symmetric about the center line Q. The second coil wire path portion 77 has an electrically conductive pattern which when rotated about the center line Q, overlaps that of the first coil wire path portion 79 or the second coil wire path portion 78.

Furthermore, the capacitor section 50BC of the LC composite component 2C according to the third modified example is configured such that at least either the first internal electrodes D53 or the second internal electrodes D54 are symmetric with respect to the element body center plane M above and below the element body center plane M.

The LC composite component 2C is configured such that the first internal electrodes D53 and the second internal electrodes D54 are symmetric with respect to the element body center O (the center of the element body) when viewed in the layering direction. Furthermore, the LC composite component 2C is configured such that when viewed in the layering direction, the first coil wire path portion 76 of the first inductor section 30C and the first coil wire path portion 79 of the second inductor section 30D are disposed to be symmetric with respect to the element body center O. Furthermore, the LC composite component 2C is configured such that the second coil wire path portion 77 of the first inductor section 30C and the second coil wire path portion 78 of the second inductor section 30D are disposed to be symmetric about the center when viewed in the layering direction.

Alternatively, the LC composite component 2C may be configured such that the first coil wire path portion 76 of the first inductor section 30C and the second coil wire path portion 78 of the second inductor section 30D should be disposed to be symmetric with respect to the element body center O when viewed in the layering direction, while the second coil wire path portion 77 of the first inductor section 30C and the first coil wire path portion 79 of the second inductor section 30D should be disposed to be symmetric with respect to the center O when viewed in the layering direction.

This structure can eliminate the mounting directivity of the LC composite component. This can reduce the alignment work of the mounting direction of the LC composite component 2C when the LC composite component 2C is mounted onto the circuit board. Furthermore, the aforementioned structure enables the LC composite component 2C to be employed as an LC filter having constant properties because the properties of the LC composite component 2C do not vary depending on the mounting direction.

### Third Embodiment

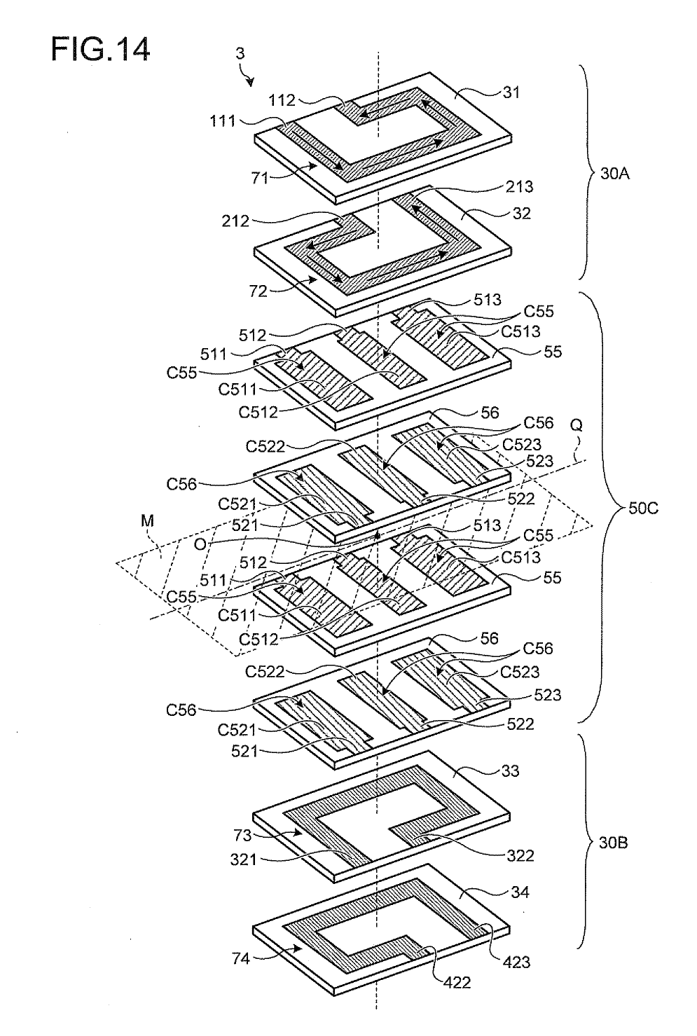

FIG. 14 is an exploded perspective view illustrating the main portion of the element body of an LC composite component according to a third embodiment. FIG. 14 illustrates the element body 10 which is decomposed in the layering order except for the aforementioned insulator layers 17, 18, and 19. The LC composite component 3 according to this embodiment includes a capacitor section 50C, the first inductor section 30A, and the second inductor section 30B. The LC composite component 3 is configured such that the external conductors 12 and 22 for connecting to the first coil wire path portions 71 and 74 and the second coil wire path portions 72 and 73 of the LC composite component 1 are connected with first internal electrodes C55 and second internal electrodes C56, respectively. In the descriptions below, the same components as those described in relation to the aforementioned embodiments will be denoted by the same reference signs without repeating the same explanations.

As shown in FIG. 14, the LC composite component 3 is configured such that the capacitor section and the inductor sections are alternately stacked in layers in the order of the first inductor section 30A, the capacitor section 50C, and the second inductor section 30B. The LC composite component 3 is configured such that the first inductor section 30A and the second inductor section 30B are symmetric with respect to the capacitor section 50C in the layering direction. This allows the first inductor section 30A and the second inductor section 30B to be disposed close to the first element body principal face 10a and the second element body principal face 10b of the LC composite component 3.

For example, the first internal electrodes C55 and the second internal electrodes C56 of the capacitor section 50C, to be described later, are disposed at the same position and the same distance with respect to the element body center O. Furthermore, the first coil wire path portion 71 of the first inductor section 30A and the first coil wire path portion 74 of the second inductor section 30B are disposed at the same position and the same distance with respect to the element body center O. Furthermore, the second coil wire path portion 72 of the first inductor section 30A and the second coil wire path portion 73 of the second inductor section 30B are disposed at the same position and the same distance with respect to the element body center O.

The capacitor section 50C shown in FIG. 14 is formed on the surface of insulator layers 55 and 56, and includes the first internal electrodes C55 formed on the surface of the insulator layers 55 and the second internal electrodes C56 formed on the surface of the insulator layers 56. The first internal electrodes C55 each have an extraction electrode portion 511, 512, or 513 which is formed of electrical conductor on the surface of the insulator layers 55 and a first principal face electrode portion C511, C512, or C513 which is also formed of electrical conductor on the surface of the insulator layers 55. The second internal electrodes C56 each have an extraction electrode portion 521, 522, or 523 which is formed of electrical conductor on the surface of the insulator layers 56 and a second principal face electrode portion C521, C522, or C523 which is also formed of electrical conductor on the surface of the insulator layers 56.

The extraction electrode portions 511, 512, and 513 of the first internal electrodes C55 are drawn out to the first element body side face 10c and then connected to the external conductors 11, 12, and 13 of the first external conductor group 15 shown in FIG. 1. On the other hand, the extraction electrode portions 521, 522, and 523 of the second internal electrodes C56 are drawn out to the second element body side face 10d and then connected to the external conductors 21, 22, and 23 of the second external conductor group 25 shown in FIG. 1.

The extraction electrode portions 512 and 522 and the principal face electrode portions C512 and C522 are made of the same material as that of the extraction electrode portions 511, 513, 521, and 523 and the principal face electrode portions C511, C513, C521, and C523. In this embodiment, the capacitor section 50C has the insulator layers 55, 56, 55, and 56 stacked in that order from the first element body principal face 10a toward the second element body principal face 10b. The capacitor section 50C includes at least one “unit of capacitor” (capacitor unit) which has the first internal electrodes C55, the insulation layer 55, the second internal electrodes C56, and the insulator layer 56 stacked in that order. The capacitor section 50C only has to include such a number of capacitor units that can provide the capacitance required of the specification of the LC composite component 3, with no limitation on the number.

The extraction electrode portion 512 is formed on the surface of the insulator layer 55. On the surface of the insulator layer 55, the extraction electrode portion 512 is spaced apart from the extraction electrode portions 511 and 513 by a predetermined distance so as to be electrically insulated from each other. This distance is the same as the distance between the adjacent external conductor portions 11c, 12c, and 13c. The extraction electrode portions 511, 512, and 513 are disposed on the first element body side face 10c side. This allows the extraction electrode portion 512 to be electrically connected to the external conductor portion 12c.

The extraction electrode portion 512 is electrically connected to the principal face electrode portion C512. The principal face electrode portion C512 is formed on the surface of the insulator layer 55. The principal face electrode portions C511, C512, and C513 are spaced apart from each other by a predetermined distance so as to be electrically insulated from each other on the surface of the insulator layer 55, and have a greater area than that of the extraction electrode portions 511, 512, and 513.

The extraction electrode portion 522 is formed on the surface of the insulator layer 56. On the surface of the insulator layer 56, the extraction electrode portion 522 is spaced apart from the extraction electrode portions 521 and 523 by a predetermined distance so as to be electrically insulated from each other. This distance is the same as the distance between the adjacent external conductor portions 21d, 22d, and 23d. The extraction electrode portions 521, 522, and 523 are disposed on the second element body side face 10d side. This allows the extraction electrode portion 522 to be electrically connected to the external conductor portion 22d.

The extraction electrode portion 522 is electrically connected to the principal face electrode portion C522. The principal face electrode portion C522 is formed on the surface of the insulator layer 56. The principal face electrode portions C521, C522, and C523 are spaced apart from each other by a predetermined distance so as to be electrically insulated from each other on the surface of the insulator layer 56, and have a greater area than that of the extraction electrode portions 521, 522, and 523.

The principal face electrode portions C511, C512, and C513 of the first internal electrodes C55 and the principal face electrode portions C521 C522, and C523 of the second internal electrodes C56 are drawn out in mutually opposite directions to the first element body side face 10c and the second element body side face 10d via the extraction electrode portions 511, 512, and 513 and the extraction electrode portions 521, 522, and 523.

Furthermore, the capacitor section 50C is configured such that the principal face electrode portions C511, C512, and C513 are opposed to the principal face electrode portions C521, C522, and C523 in the layering direction via an insulator. This allows the capacitor section 50C to serve as a multilayer capacitor in which capacitance will be developed between the principal face electrode portions C511, C512, and C513 and the principal face electrode portions C521, C522, and C523.

At least the two external conductors 11 and 13 other than the external conductor 12 connecting to the first coil wire path portion 71 and the second coil wire path portion 72 of the first inductor section 30A are connected with the respective first internal electrode C55 of the capacitor section 50C. Furthermore, at least the two external conductors 21 and 23 other than the external conductor 22 connecting to the first coil wire path portion 74 and the second coil wire path portion 73 of the second inductor section 30B are connected with the respective second internal electrode C56 of the capacitor section 50C.

Furthermore, the LC composite component 3 is configured such that the external conductor 12 is connected with the first internal electrode C55 of the capacitor section 50, while the external conductor 22 connecting to the first coil wire path portion 74 and the second coil wire path portion 73 of the second inductor section 30B is connected with the second internal electrode C56 of the capacitor section 50C. This structure allows the external conductors 11, 12, 13, 21, 22, and 23 to connect between the inductor section 30A, the inductor section 30B, and the capacitor section 50C.

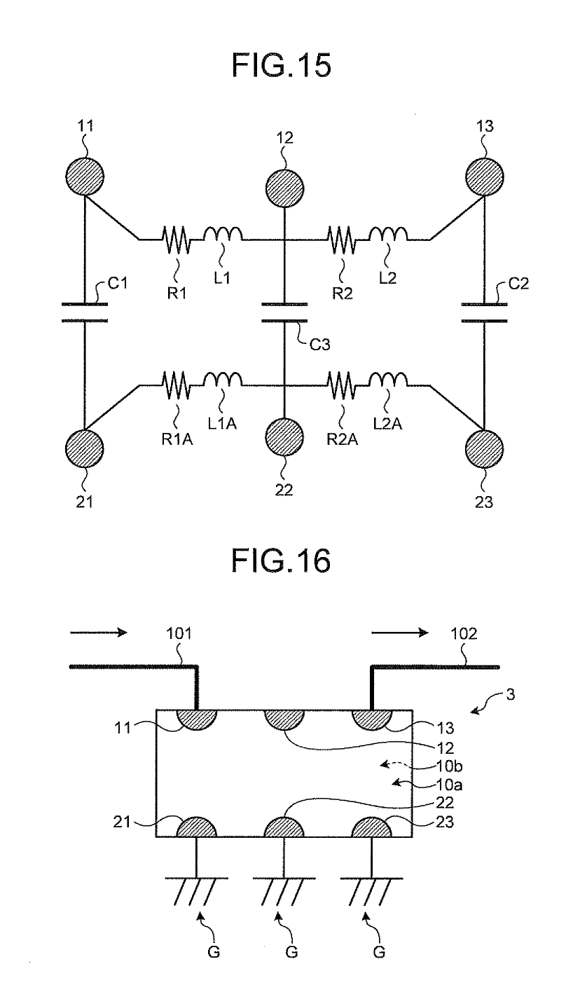

FIG. 15 is an explanatory view illustrating an equivalent circuit of the LC composite component according to the third embodiment. The equivalent circuit shown in FIG. 15 has the external conductors 11, 12, 13, 21, 22, and 23, the inductor L1, the inductor internal resistor R1, the inductor L2, the inductor internal resistor R2, the capacitor C1, the capacitor C2, a capacitor C3, the inductor L1A, the inductor internal resistor R1A, the inductor L2A, and the inductor internal resistor R2A.

The inductor L1 and the inductor internal resistor R1 are formed by the first coil wire path portion 71 of the aforementioned first inductor section 30A. In the equivalent circuit, the inductor L1 and the inductor internal resistor R1 are connected in series between the external conductors 11 and 12. Furthermore, the inductor L2 and the inductor internal resistor R2 are formed by the second coil wire path portion 72 of the first inductor section 30A. In the equivalent circuit, the inductor L2 and the inductor internal resistor R2 are connected in series between the external conductors 12 and 13.

The capacitor C1 is formed by the principal face electrode portions C511 and C521 of the aforementioned capacitor section 50C. The capacitor C1 is connected between the external conductors 11 and 21. Furthermore, the capacitor C2 is formed by the principal face electrode portions C513 and C523 of the capacitor section 50C. The capacitor C2 is connected between the external conductors 13 and 23. Furthermore, the capacitor C3 is formed by the principal face electrode portions C512 and C522 of the capacitor section 50C. The capacitor C3 is connected between the external conductors 12 and 22.

The inductor L1A and the inductor internal resistor R1A are formed by the second coil wire path portion 73 of the aforementioned second inductor section 30B. In the equivalent circuit, the inductor L1A and the inductor internal resistor R1A are connected in series between the external conductors 21 and 22. Furthermore, the inductor L2A and the inductor internal resistor R2A are formed by the first coil wire path portion 74 of the second inductor section 30B. In the equivalent circuit, the inductor L2A and the inductor internal resistor R2A are connected in series between the external conductors 22 and 23.

FIG. 16 is an explanatory view illustrating an example of connection between the LC composite component according to the third embodiment and signal lines. In the example, the LC composite component 3 is shown with the second element body principal face 10b opposed to a circuit board, in which the LC composite component 3 is connected to the signal lines 101 and 102. At least the two external conductors 11 and 13 other than the external conductor 12 connecting to the first coil wire path portion 71 and the second coil wire path portion 72 of the first inductor section 30A are electrically connected to the signal lines 101 and 102 of the circuit board, respectively. Furthermore, the external conductors 21, 22, and 23 connected to the second internal electrodes C56 of the capacitor section are electrically connected to the GND line G of the circuit board.

As shown in FIG. 16, for example, the external conductor 11 and the external conductor 13 are connected to the signal line 101 and the signal line 102, respectively. Accordingly, the external conductor 11 serves as a signal input terminal electrode into which a signal is input. On the other hand, the external conductor 13 serves as a signal output terminal electrode from which a signal is output. The external conductors 21, 22, and 23 are connected to the GND line G and grounded. Accordingly, the external conductors 21, 22, and 23 serve as a GND terminal electrode. The external conductor 12 serves as what is called an external connection conductor that is not directly connected to the circuit board. The external conductor 12 connects the first coil wire path portion 71 and the second coil wire path portion 72 of the inductor section 30A, but is not connected to the circuit board.

This connection structure causes the inductors L1A and L2A not to operate in the equivalent circuit shown in FIG. 15, but allows the LC composite component 3 to operate as a noise filter. Furthermore, the LC composite component 3 is configured such that the capacitor C3 is connected between the external conductors 12 and 22. Accordingly, when compared with the LC composite component 1 shown in FIG. 6, a more abrupt cutoff-frequency characteristic can be provided to the noise component contained in the input signal. As a result, the LC composite component 3 operates as an LC filter which has a more accurate cutoff-frequency in the noise band that is desired to cut.

As the second mounting structure, the LC composite component 3 may be configured such that with the second element body principal face 10b opposed to the circuit board, of the external conductors 11, 12, 13, 21, 22, and 23, the external conductor 23 should be connected to the signal line 101 and the external conductor 21 should be connected to the signal line 102. In this case, the external conductor 23 serves as a signal input terminal electrode into which a signal is input. Furthermore, the external conductor 21 serves as a signal output terminal electrode from which a signal is output. The external conductor 22 serves as what is called an external connection conductor that is not directly connected to the circuit board.

In the second mounting structure, the external conductors 11, 12, and 13 are connected to the GND line G and grounded. Accordingly, the external conductors 11, 12, and 13 serve as a GND terminal electrode. This causes the inductors L1 and L2 not to operate in the equivalent circuit shown in FIG. 15, but allows the LC composite component 3 to operate as a noise filter.

As the third mounting structure, the LC composite component 3 may be configured such that with the first element body principal face 10a opposed to the circuit board, of the external conductors 11, 12, 13, 21, 22, and 23, the external conductor 13 should be connected to the signal line 101, while the external conductor 11 should be connected to the signal line 102. In this case, the external conductor 13 serves as a signal input terminal electrode into which a signal is input. Furthermore, the external conductor 11 serves as a signal output terminal electrode from which a signal is output. Furthermore, the external conductor 12 serves as what is called an external connection conductor that is not directly connected to the circuit board.

In the third mounting structure, the external conductors 21, 22, and 23 are connected to the GND line G and grounded. Accordingly, the external conductors 21, 22, and 23 serve as a GND terminal electrode. This causes the inductors L1A and L2A not to operate in the equivalent circuit shown in FIG. 15, but allows the LC composite component 3 to operate as a noise filter.

As the fourth mounting structure, the LC composite component 3 may be configured such that with the first element body principal face 10a opposed to the circuit board, of the external conductors 11, 12, 13, 21, 22, and 23, the external conductor 21 should be connected to the signal line 101, while the external conductor 23 should be connected to the signal line 102. In this case, the external conductor 21 serves as a signal input terminal electrode into which a signal is input. Furthermore, the external conductor 23 serves as a signal output terminal electrode from which a signal is output. Furthermore, the external conductor 22 serves as what is called an external connection conductor that is not directly connected to the circuit board.

In the fourth mounting structure, the external conductors 11, 12, and 13 are connected to the GND line G and grounded. Accordingly, the external conductors 11, 12, and 13 serve as a GND terminal electrode. This causes the inductors L1 and L2 not to operate in the equivalent circuit shown in FIG. 15, but allows the LC composite component 3 to operate as a noise filter.

As described above, the LC composite component 3 is capable of operating as an equivalent π-type noise filter when seen from the signal lines 101 and 102 even when any one of the first element body principal face 10a and the second element body principal face 10b is opposed to the circuit board. Furthermore, when viewed in the layering direction, the LC composite component 3 is capable of operating as an equivalent π-type noise filter when seen from the signal lines 101 and 102 even when the LC composite component 3 is rotated by 180° about the element body center O within the circuit board plane. This can reduce the alignment work of the mounting direction of the LC composite component 3 when being mounted onto the circuit board. Furthermore, the aforementioned structure enables the LC composite component 3 to be employed as an LC filter having constant properties because the properties of the LC composite component 3 do not vary depending on the mounting direction.

### Fourth Embodiment

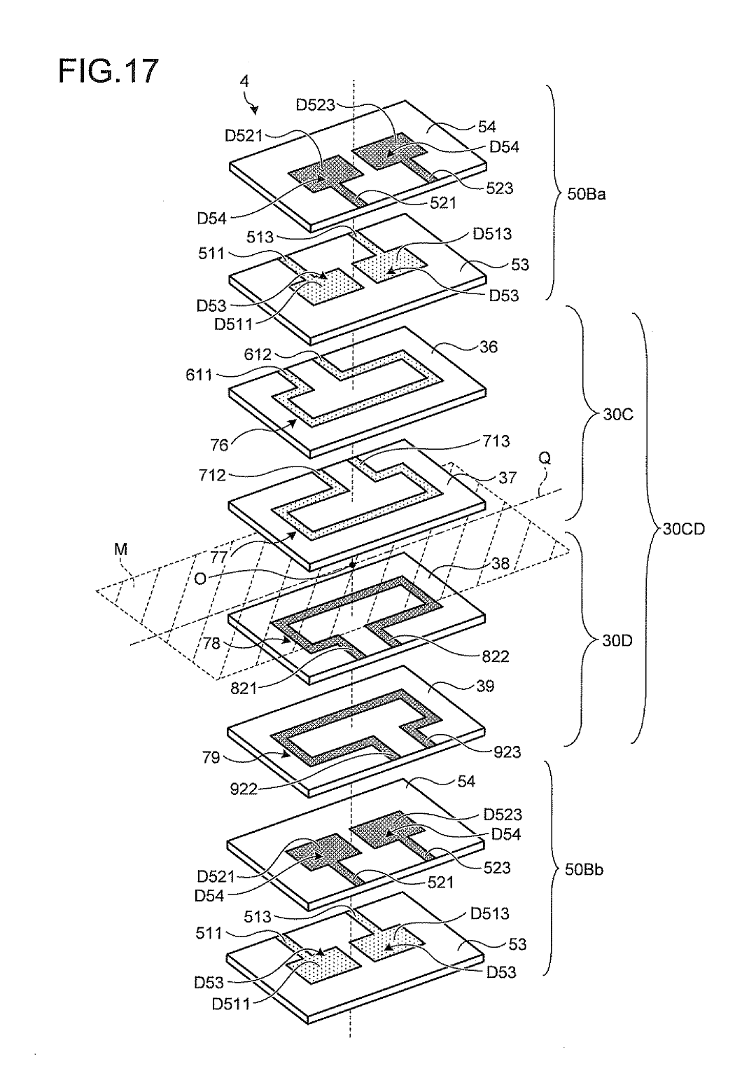

FIG. 17 is an exploded perspective view illustrating the main portion of the element body of an LC composite component according to a fourth embodiment. FIG. 17 illustrates the element body 10 which is decomposed in the layering order except for the aforementioned insulator layers 17, 18, and 19. In the descriptions below, the same components as those described in relation to the aforementioned embodiments will be denoted by the same reference signs without repeating the same explanations. The LC composite component 4 according to this embodiment is configured such that a first capacitor section 50Ba and a second capacitor section 50Bb are disposed on the first element body principal face 10a side and the second element body principal face 10b side of the LC composite component 4, respectively.

The LC composite component 4 includes the first capacitor section 50Ba, the second capacitor section 50Bb, the first inductor section 30C, and the second inductor section 30D. The first inductor section 30C and the second inductor section 30D are successively stacked in layers to be thereby integrated into an inductor section 30CD. Thus, the capacitor sections and the inductor section are alternately stacked in layers in the order of the first capacitor section 50Ba, the inductor section 30CD, and the second capacitor section 50Bb. The LC composite component 4 is configured such that the first capacitor section 50Ba and the second capacitor section 50Bb are symmetric with respect to the inductor section 30CD in the layering direction.

The first capacitor section 50Ba and the second capacitor section 50Bb each include the first internal electrodes D53 and the second internal electrodes D54 which are formed on the surface of the insulator layers 54 and 53 and opposed to each other in the layering direction. The first capacitor section 50Ba and the second capacitor section 50Bb are multilayer capacitors which have the same capacitance.

The extraction electrode portions 511 and 513 of the first internal electrodes D53 are drawn out to the first element body side face 10c and then connected to the external conductors 11 and 13 of the first external conductor group 15 shown in FIG. 1. On the other hand, the extraction electrode portions 521 and 523 of the second internal electrodes D54 are drawn out to the second element body side face 10d and then connected to the external conductors 21 and 23 of the second external conductor group 25 shown in FIG. 1.

When the LC composite component is mounted on the circuit board, there may be developed a very small inductance component or Equivalent Series Inductance (L) (ESL) between the capacitor section and the circuit board.

When mounted on the circuit board, the LC composite component 4 is connected thereto so that either the first capacitor section 50Ba or the second capacitor section 50Bb is located near the circuit board. Accordingly, when compared with the LC composite component 2 of the aforementioned second embodiment, the LC composite component 4 has a shorter distance from the circuit board to the first internal electrodes D53 or the second internal electrodes D54. As a result, the LC composite component 4 can reduce the ESL that may be developed between the first capacitor section 50Ba or the second capacitor section 50Bb and the circuit board.

As described above, the LC composite component 4 is configured such that the capacitor sections and the inductor section are alternately stacked in layers in the order of the first capacitor section 50Ba, the inductor section 30CD, and the second capacitor section 50Bb. The first capacitor section 50Ba and the second capacitor section 50Bb are symmetric with respect to the inductor section 30CD in the layering direction. This allows the first capacitor section 50Ba and the second capacitor section 50Bb to be disposed on the first element body principal face 10a side and the second element body principal face 10b side of the LC composite component 4.

The aforementioned structure allows the LC composite component 4 to be configured such that the first internal electrodes D53 or the second internal electrodes D54 included in the first capacitor section 50Ba or the second capacitor section 50Bb are located closest to the circuit board, thereby reducing the ESL.

Furthermore, the first coil wire path portion 76 (79) and the second coil wire path portion 77 (78) are connected by an external connection conductor, which is not mounted, thus providing an elongated electrically conductive path. As a result, the electrically conductive path of the spiral coil is elongated, thereby providing an increased inductance component.

The first inductor section 30C and the second inductor section 30D are separately disposed above and below the element body center O in the layering direction. Furthermore, the first internal electrodes D53 and the second internal electrodes D54 are disposed at the same position and the same distance with respect to the element body center O.

Furthermore, the LC composite component 4 is configured such that the first coil wire path portion 76 of the first inductor section 30C and the first coil wire path portion 79 of the second inductor section 30D are disposed at the same position and the same distance with respect to the element body center O. In the same manner, the LC composite component 4 is also configured such that the second coil wire path portion 77 of the first inductor section 30C and the second coil wire path portion 78 of the second inductor section 30D are disposed at the same position and the same distance.

The LC composite component 4 is further configured such that when viewed in the layering direction, the first internal electrodes D53 and the second internal electrodes D54 are symmetric with respect to the element body center O. The LC composite component 4 is also preferably configured such that the first coil wire path portion 76 of the first inductor section 30C and the first coil wire path portion 79 of the second inductor section 30D should be disposed to be symmetric with respect to the element body center O when viewed in the layering direction, while the second coil wire path portion 77 of the first inductor section 30C and the second coil wire path portion 78 of the second inductor section 30D should be disposed to be symmetric about the center O when viewed in the layering direction.

This structure can eliminate the mounting directivity of the LC composite component 4. This can reduce the alignment work of the mounting direction of the LC composite component 4 when the LC composite component 4 is being mounted onto the circuit board. Furthermore, the aforementioned structure enables the LC composite component 4 to be employed as an LC filter having constant properties because the properties of the LC composite component 4 do not vary depending on the mounting direction.

When viewed in the layering direction, the first coil wire path portions 76 and 79 and the second coil wire path portions 77 and 78, which are included in the aforementioned first inductor section 30C and the second inductor section 30D as described above, are wound around at least one of the first principal face electrode portions D511 and D513 of the first internal electrodes D53 adjacent to the first inductor section 30C and the second principal face electrode portions D521 and D523 of the second internal electrodes D54 adjacent to the second inductor section 30D.

The first coil wire path portions 76 and 79 and the second coil wire path portions 77 and 78, which are included in the first inductor section 30C and the second inductor section 30D, are wound around on the surface of the insulator layers 36, 37, 38, and 39, avoiding the region opposed in the layering direction to the area of the principal face electrode portions D511, D513, D521, and D523 of the first capacitor section 50Ba or the second capacitor section 50Bb.

Furthermore, the region of the insulator layers 36, 37, 38, and 39 opposed in the layering direction to the principal face electrode portions D511, D513, D321, and D523 is to be defined as the region through which the first coil wire path portions 76 and 79 and the second coil wire path portions 77 and 78 will not pass. This allows the principal face electrode portions D511, D513, D521, and D523 to less overlap with the first coil wire path portions 76 and 79 and the second coil wire path portions 77 and 78 in the layering direction. As a result, it is possible to reduce the capacitance between the principal face electrode portions D511, D513, D521, and D523 and the first coil wire path portions 76 and 79 as well as the second coil wire path portions 77 and 78. Furthermore, the LC composite component 4 is improved in the properties as a noise filter.

The aforementioned structure prevents the principal face electrode portions of the capacitor sections and the coil wire path portions of the inductor section from overlapping each other in the layering direction. This can reduce the capacitance between the principal face electrode portions of the capacitor sections and the coil wire path portions of the inductor section. As a result, the LC composite component can attenuate high-frequency noise components.

### Fifth Embodiment

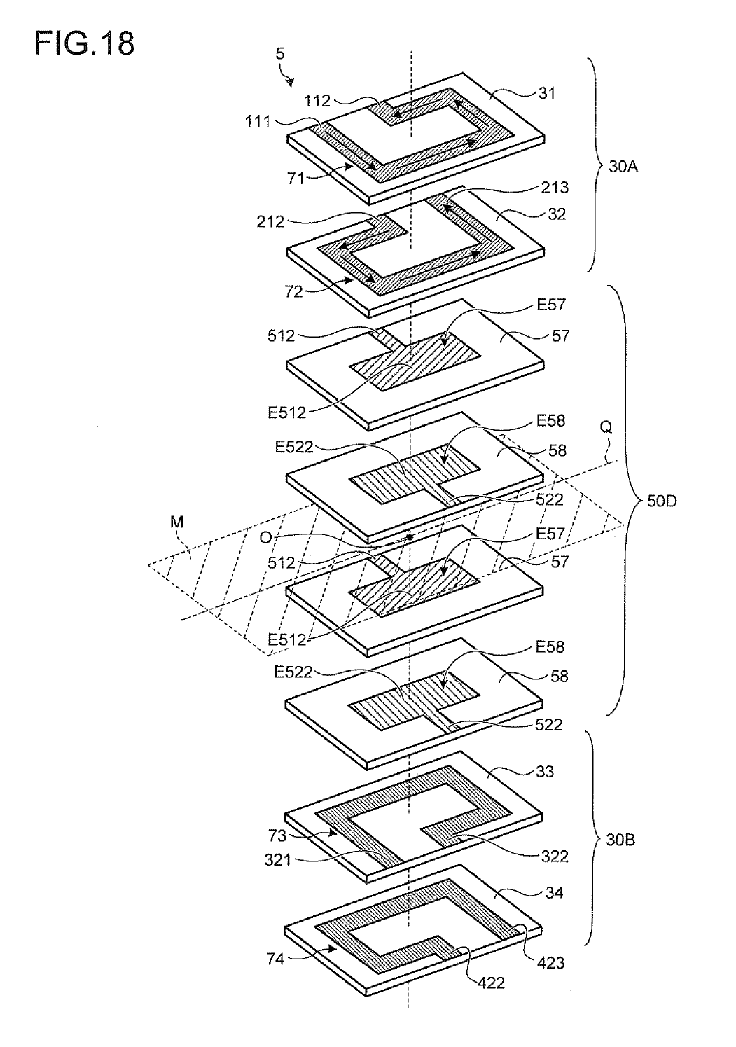

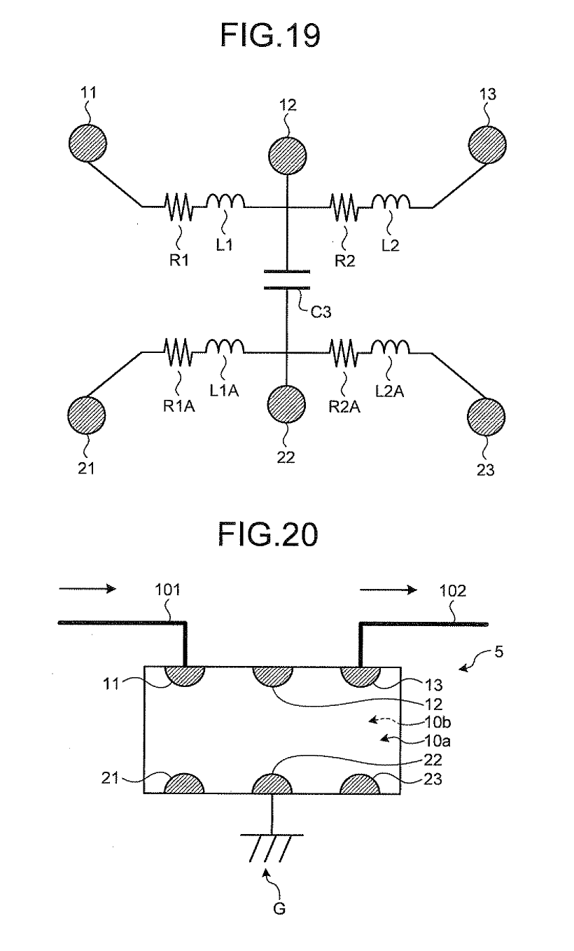

FIG. 18 is an exploded perspective view illustrating the main portion of the element body of an LC composite component according to a fifth embodiment. FIG. 18 illustrates the element body 10 which is decomposed in the layering order except for the aforementioned insulator layers 17, 18, and 19. FIG. 19 is an explanatory view illustrating the equivalent circuit of the LC composite component according to the fifth embodiment. In the descriptions below, the same components as those described in relation to the aforementioned embodiments will be denoted by the same reference signs without repeating the same explanations. The LC composite component 5 according to this embodiment has the equivalent circuit shown in FIG. 19 and operates as what is called a T-type noise filter.

The LC composite component 5 includes a capacitor section 50D, the first inductor section 30A, and the second inductor section 30B. Then, as shown in FIG. 18, the LC composite component 5 is configured such that the inductor sections and the capacitor section are alternately deposited in the order of the first inductor section 30A, the capacitor section 50D, and the second inductor section 30B. The LC composite component 5 is configured such that the first inductor section 30A and the second inductor section 30B are symmetric with respect to the capacitor section 50D in the layering direction. This allows the first inductor section 30A and the second inductor section 30B to be disposed on the first element body principal face 10a side and the second element body principal face 10b side of the LC composite component 5.

The capacitor section 50D shown in FIG. 18 includes a first internal electrode E57 formed on the surface of an insulator layer 57 and a second internal electrode E58 formed on the surface of an insulator layer 58. The first internal electrode E57 has an extraction electrode portion 512 formed of electrical conductor on the surface of the insulator layer 57 and a first principal face electrode portion E512 formed of electrical conductor on the surface of the insulator layer 57. The second internal electrode E58 has the extraction electrode portion 522 formed of electrical conductor on the surface of the insulator layer 58 and a second principal face electrode portion E522 formed of electrical conductor on the surface of the insulator layer 58.

The principal face electrode portions E512 and E522 are formed of the same material as that of the aforementioned principal face electrode portions C511, C513, C521, and C523. In this embodiment, the capacitor section 50D has layers stacked in the order of the insulator layers 57, 58, 57, and 58 from the first element body principal face 10a toward the second element body principal face 10b. The capacitor section 50D includes at least one “unit of capacitor” (capacitor unit) which has the first internal electrode E57, the insulator layer 57, the second internal electrode E58, and the insulator layer 58 stacked in layers in that order. The capacitor section 50D only has to include such a number of capacitor units that can provide the capacitance required of the specification of the LC composite component 5, with no limitation on the number.

The extraction electrode portion 512 is formed on the surface of the insulator layer 57. The extraction electrode portion 512 is disposed on the first element body side face 10c side. This allows the extraction electrode portion 512 to be electrically connected to the external conductor portion 12c. The extraction electrode portion 512 is electrically connected to the principal face electrode portion E512. The principal face electrode portion E512 is formed on the surface of the insulator layer 57 so as to have an area greater than that of the extraction electrode portion 512.

The extraction electrode portion 522 is formed on the surface of the insulator layer 58. The extraction electrode portion 522 is disposed on the second element body side face 10d side. This allows the extraction electrode portion 522 to be electrically connected to the external conductor portion 22d. The extraction electrode portion 522 is electrically connected to the principal face electrode portion E522. The principal face electrode portion E522 is formed on the surface of the insulator layer 58 so as to have a greater area than that of the extraction electrode portion 522.

As described above, the capacitor section 50D is configured such that the principal face electrode portion E512 and the principal face electrode portion E522 are drawn out via the extraction electrode portion 512 and the extraction electrode portion 522 to the element body side faces 10c and 10d which are opposite in direction to each other (see FIG. 1). The capacitor section 50D is also configured such that the principal face electrode portion E512 and the principal face electrode portion E522 are opposed to each other in the layering direction via an insulator. This allows the capacitor section SOD to serve as a multilayer capacitor in which capacitance will be developed between the principal face electrode portion E512 and the principal face electrode portion E522.

The equivalent circuit shown in FIG. 19 has the external conductors 11, 12, 13, 21, 22, and 23, the inductor L1, the inductor internal resistor R1, the inductor L2, the inductor internal resistor R2, the capacitor C3, the inductor L1A, the inductor internal resistor R1A, the inductor L2A, and the inductor internal resistor R2A.

The inductor L1 and the inductor internal resistor R1 are formed by the coil wire path portion 71 of the aforementioned inductor section 30A. This allows the inductor L1 and the inductor internal resistor R1 to be connected in series between the external conductors 11 and 12 in the equivalent circuit. Furthermore, the inductor L2 and the inductor internal resistor R2 are formed by the coil wire path portion 72 of the inductor section 30A. This allows the inductor L2 and the inductor internal resistor R2 to be connected in series between the external conductors 12 and 13 in the equivalent circuit.

The capacitor C3 is formed by the principal face electrode portions E512 and E522 of the aforementioned capacitor section 50D. This allows the capacitor C3 to be connected between the external conductors 12 and 22.

The inductor L1A and the inductor internal resistor R1A are formed by the coil wire path portion 73 of the aforementioned inductor section 30B. This allows the inductor L1A and the inductor internal resistor R1A to be connected in series between the external conductors 21 and 22 in the equivalent circuit. Furthermore, the inductor L2A and the inductor internal resistor R2A are formed by the coil wire path portion 74 of the inductor section 30B. This allows the inductor L2A and the inductor internal resistor R2A to be connected in series between the external conductors 22 and 23 in the equivalent circuit.

FIG. 20 is an explanatory view illustrating an example of connection between the LC composite component according to the fifth embodiment and signal lines. In the example, the LC composite component 5 is shown with the second element body principal face 10b opposed to the circuit board, in which the LC composite component 5 is connected to the signal lines 101 and 102. At least the two external conductors 11 and 13 other than the external conductor 12 connecting to the first coil wire path portion 71 and the second coil wire path portion 72 of the first inductor section 30A are electrically connected to the signal lines 101 and 102 of the circuit board. Furthermore, the external conductor 22 which is connected at least to the second internal electrode E58 of the capacitor section 50D is electrically connected to the GND line G of the circuit board.

As shown in FIG. 20, for example, the external conductor 11 and the external conductor 13 of the external conductors 11, 12, 13, 21, 22, and 23 are connected to the signal line 101 and the signal line 102, respectively. In this case, the external conductor 11 serves as a signal input terminal electrode into which a signal is input. Furthermore, the external conductor 13 serves as a signal output terminal electrode from which a signal is output. Furthermore, at least the external conductor 22 is connected to the GND line G and grounded. In this case, the external conductor 22 serves as a GND terminal electrode.

The external conductor 12 serves as what is called an external connection conductor that is not directly connected to the circuit board. That is, the external conductor 12 connects the first coil wire path portion 71 and the second coil wire path portion 72 of the inductor section 30A, but is not connected to the circuit board. Note that the external conductors 21 and 23 may also be employed as what is called an external connection conductor that is not directly connected to the circuit board or alternatively as a GND terminal electrode which is connected to the GND line G and grounded.

This causes the inductors L1A and L2A not to operate in the equivalent circuit shown in FIG. 19, but allows the LC composite component 5 to operate as what is called a T-type noise filter (T-type circuit).

As the second mounting structure, the LC composite component 5 may be configured such that with the second element body principal face 10b opposed to the circuit board, of the external conductors 11, 12, 13, 21, 22, and 23, the external conductor 23 is connected to the signal line 101 and the external conductor 21 is connected to the signal line 102. In this case, the external conductor 23 serves as a signal input terminal electrode into which a signal is input. Furthermore, the external conductor 21 serves as a signal output terminal electrode from which a signal is output. Furthermore, the external conductor 22 serves as what is called an external connection conductor that is not directly connected to the circuit board.

In the second mounting structure, at least the external conductor 12 is connected to the GND line G and grounded. In this case, the external conductor 12 serves as a GND terminal electrode. Note that the external conductors 11 and 13 may also be employed as what is called an external connection conductor that is not directly connected to the circuit board or alternatively as a GND terminal electrode which is connected to the GND line G and grounded. This causes the inductors L1 and L2 not to operate in the equivalent circuit shown in FIG. 19, but allows the LC composite component 5 to operate as what is called a T-type noise filter.

As the third mounting structure, the LC composite component 5 may be configured such that with the first element body principal face 10a opposed to the circuit board, of the external conductors 11, 12, 13, 21, 22, and 23, the external conductor 13 is connected to the signal line 101 and the external conductor 11 is connected to the signal line 102. In this case, the external conductor 13 serves as a signal input terminal electrode into which a signal is input. Furthermore, the external conductor 11 serves as a signal output terminal electrode from which a signal is output. Furthermore, the external conductor 12 serves as what is called an external connection conductor that is not directly connected to the circuit board.

In the third mounting structure, at least the external conductor 22 is connected to the GND line G and grounded. In this case, the external conductor 22 serves as a GND terminal electrode. Note that the external conductors 21 and 23 may also be employed as what is called an external connection conductor that is not directly connected to the circuit board or alternatively as a GND terminal electrode which is connected to the GND line G and grounded. This causes the inductors L1A and L2A not to operate in the equivalent circuit shown in FIG. 19, but allows the equivalent circuit to operate as what is called a T-type noise filter.

As the fourth mounting structure, the LC composite component 5 may be configured such that with the first element body principal face 10a opposed to the circuit board, of the external conductors 11, 12, 13, 21, 22, and 23, the external conductor 21 is connected to the signal line 101 and the external conductor 23 is connected to the signal line 102. In this case, the external conductor 21 serves as a signal input terminal electrode into which a signal is input. Furthermore, the external conductor 23 serves as a signal output terminal electrode from which a signal is output. Furthermore, the external conductor 22 serves as what is called an external connection conductor that is not directly connected to the circuit board.

In the fourth mounting structure, at least the external conductor 12 is connected to the GND line G and grounded. Accordingly, the external conductor 12 serves as a GND terminal electrode. Note that the external conductors 11 and 13 may also be employed as what is called an external connection conductor that is not directly connected to the circuit board or alternatively as a GND terminal electrode which is connected to the GND line G and grounded. This causes the inductors L1 and L2 not to operate in the equivalent circuit shown in FIG. 19, but allows the LC composite component 5 to operate as what is called a T-type noise filter.

Like the LC composite component 1, the LC composite component 5 is capable of operating as an equivalent T-type noise filter when seen from the signal lines 101 and 102 even when either the first element body principal face 10a or the second element body principal face 10b is connected to the circuit board. Furthermore, when viewed in the layering direction, the LC composite component 5 is capable of operating as an equivalent T-type noise filter when seen from the signal lines 101 and 102 even when the LC composite component 5 is rotated by 180° about the element body center O within the circuit board plane. Accordingly, This can reduce the alignment work of the mounting direction of the LC composite component 5 when the LC composite component 5 is being mounted onto the circuit board. Furthermore, the aforementioned structure enables the LC composite component 5 to be employed as an LC filter having constant properties because the properties of the LC composite component 5 do not vary depending on the mounting direction.

The first inductor section 30A includes the first coil wire path portion 71 and the second coil wire path portion 72, while the second inductor section 30B includes the first coil wire path portion 74 and the second coil wire path portion 73. The LC composite component 5 is configured such that the first inductor section 30A, the capacitor section 50D, and the second inductor section 30B are alternately stacked in that order one on another in the layering direction, and the first inductor section 30A and the second inductor section 30B are disposed near the first element body principal face 10a and the second element body principal face 10b, respectively.

Then, the external conductor 12 connecting to the first coil wire path portion 71 and the second coil wire path portion 72 of the first inductor section 30A is connected with the first internal electrode E57 of the capacitor section 50D. On the other hand, the external conductor 22 connecting to the first coil wire path portion 74 and the second coil wire path portion 73 of the second inductor section 30B is preferably connected with the second internal electrode E58 of the capacitor section 50D.

The first inductor section 30A is configured such that the first coil wire path portion 71 and the second coil wire path portion 72 are connected to the external conductor 12 shown in FIG. 1. This causes the first coil wire path portion 71 and the second coil wire path portion 72 to serve as a spiral coil which is wound in a helical fashion along the layering direction.

Furthermore, the second inductor section 30B is configured such that the first coil wire path portion 74 and the second coil wire path portion 73 are connected to the external conductor 22 shown in FIG. 1. This causes the first coil wire path portion 74 and the second coil wire path portion 73 to serve as a spiral coil which is wound in a helical fashion along the layering direction.

This structure allows the LC composite component 5 to have the capacitor section and the inductor sections and thus form an LC filter. Furthermore, the LC composite component 5 is configured such that the capacitor section and the inductor sections are formed so as to be symmetric in the layering direction. Furthermore, the LC composite component 5 has no mounting directivity because the external conductor near the first element body end face and the external conductor near the second element body end face serve as a terminal electrode, while the external conductor disposed therebetween serves as an external connection conductor. Then, the LC composite component 5 is capable of forming a T-type circuit.

The first inductor section 30A is preferably configured such that the first coil wire path portion 71 and the second coil wire path portion 72 should be drawn out to the first element body side face 10c, to which the first internal electrode E57 is drawn out, so as to be adjacent to the first internal electrode E57 in the layering direction. Alternatively, the second inductor section 30B is preferably configured such that the first coil wire path portion 74 and the second coil wire path portion 73 should be drawn out to the second element body side face 10d, to which the second internal electrode E58 is drawn out, so as to be adjacent to the second internal electrode E58 in the layering direction.

This structure allows the inductor sections and the capacitor section to be adjacent to each other with the same polarity. For example, the capacitor section and the inductor sections being adjacent to each other in different polarities would cause capacitance to be developed between the inductor sections and the capacitor section, resulting in the inductor sections and the capacitor section being coupled to each other. This may possibly lead to deterioration in noise attenuating performance and thus insufficient removal of noise components. The aforementioned structure is capable of enhancing the noise attenuating performance and removing noise components because the inductor sections and the capacitor section are adjacent to each other with the same polarity.

The first inductor section 30A and the second inductor section 30B are separately disposed above and below the element body center O in the layering direction. Furthermore, the first internal electrodes E57 and the second internal electrodes E58 are disposed at the same position and the same distance with respect to the element body center O.

Furthermore, with respect to the element body center O, the first coil wire path portion 71 of the first inductor section 30A and the first coil wire path portion 74 of the second inductor section 30B are disposed at the same position and the same distance, while the second coil wire path portion 72 of the first inductor section 30A and the second coil wire path portion 73 of the second inductor section 30B are disposed at the same position and the same distance.

It is also preferable that the first internal electrodes E57 and the second internal electrodes E58 should be symmetric with respect to the element body center O when viewed in the layering direction, and the first coil wire path portion 71 of the first inductor section 30A and the first coil wire path portion 74 of the second inductor section 30B should be disposed to be symmetric with respect to the element body center O when viewed in the layering direction, while the second coil wire path portion 72 of the first inductor section 30A and the second coil wire path portion 73 of the second inductor section 30B should be disposed to be symmetric about the center O when viewed in the layering direction.

This structure can eliminate the mounting directivity of the LC composite component 5. This can reduce the alignment work of the mounting direction of the LC composite component 5 when the LC composite component 5 is mounted on the circuit board. Furthermore, the aforementioned structure enables the LC composite component 5 to be employed as an LC filter having constant properties because the properties of the LC composite component 5 do not vary depending on the mounting direction.

The LC composite component 5 is more preferably configured such that the first coil wire path portions 71 and 74 and the second coil wire path portions 72 and 73 of the first inductor section 30A and the second inductor section 30B should be wound around at least one of the first principal face electrode portion E512 of the first internal electrode E57 and the second principal face electrode portion E522 of the second internal electrode E58 when viewed in the layering direction.

This allows the first coil wire path portions 71 and 74 and the second coil wire path portions 72 and 73 of the first inductor section 30A and the second inductor section 30B to be wound around on the surface of the insulator layers 31, 32, 33, and 34, avoiding the region opposed in the layering direction to the area of the principal face electrode portions E512 and E522 of the capacitor section 50D.

Furthermore, the region of the insulator layers 31, 32, 33, and 34 opposed to the principal face electrode portions E512 and E522 in the layering direction is to be defined as the region through which the coil wire path portions 71, 72, 73, and 74 will not pass. As a result, the area that the principal face electrode portions E512 and E522 have will less overlap with the coil wire path portions 71, 72, 73, and 74 in the layering direction. This can reduce the capacitance between the principal face electrode portions E512 and E522 and the coil wire path portions 71, 72, 73, and 74.

The LC composite component 5 can serve as a noise filter which is capable of reducing higher-frequency noise components because the capacitance between the principal face electrode portions E512 and E522 and the coil wire path portions 71, 72, 73, and 74 can be reduced.

### Sixth Embodiment

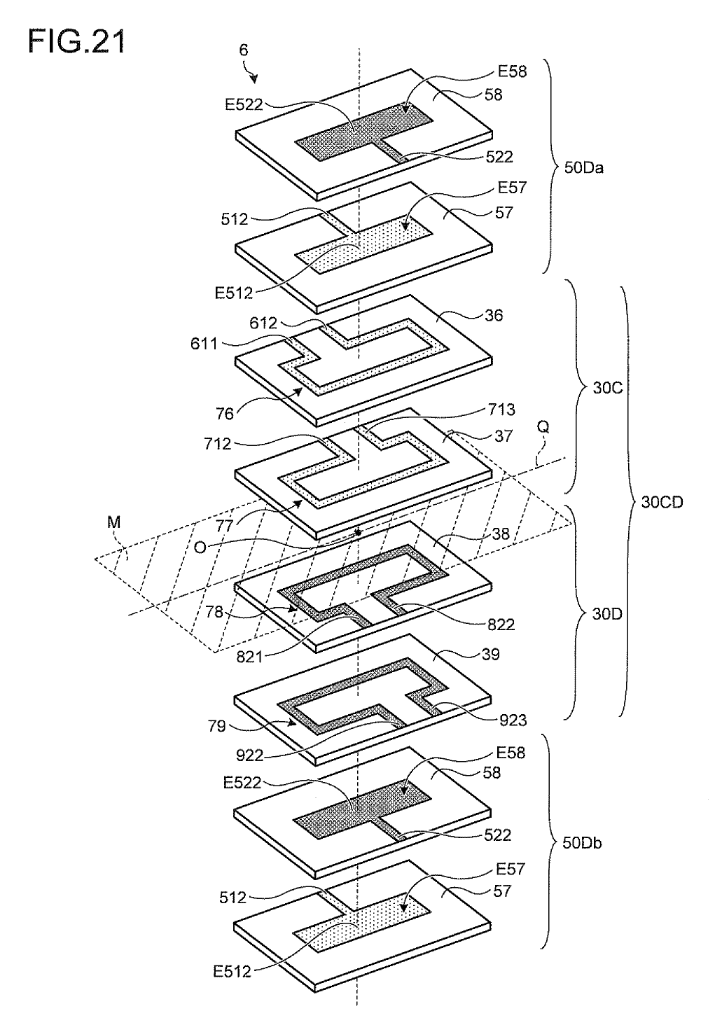

FIG. 21 is an exploded perspective view illustrating the main portion of the element body of an LC composite component according to a sixth embodiment. FIG. 21 illustrates the element body 10 which is decomposed in the layering order except for the aforementioned insulator layers 17, 18, and 19. In the descriptions below, the same components as those described in relation to the aforementioned embodiments will be denoted by the same reference signs without repeating the same explanations. The LC composite component 6 according to this embodiment is configured such that a first capacitor section 50Da and a second capacitor section 50Db are disposed on the first element body principal face 10a side and the second element body principal face 10b side of the LC composite component 6, respectively. Furthermore, the equivalent circuit of the LC composite component 6 operates as what is called a T-type noise filter.

The LC composite component 6 includes the first capacitor section 50Da, the second capacitor section 50Db, the first inductor section 30C, and the second inductor section 30D. The first inductor section 30C and the second inductor section 30D are successively stacked in layers and thereby integrated into the inductor section 30CD.

Thus, the LC composite component 6 is configured such that the capacitor sections and the inductor section are alternately stacked in layers in the order of the first capacitor section 50Da, the inductor section 30CD, and the second capacitor section 50Db. The LC composite component 6 is also configured such that the first capacitor section 50Da and the second capacitor section 50Db are symmetric with respect to the inductor section 30CD in the layering direction.

The first capacitor section 50Da and the second capacitor section 50Db include the first internal electrode E57 and the second internal electrode E58 which are formed on the surface of the insulator layers 58 and 57 and opposed to each other in the layering direction. The first capacitor section 50Da and the second capacitor section 50Db are multilayer capacitors which has the same capacitance.

The extraction electrode portion 512 of the first internal electrode E57 is drawn out to the first element body side face 10c and then connected to the external conductor 12 of the first external conductor group 15 shown in FIG. 1. Furthermore, the extraction electrode portion 522 of the second internal electrode E58 is drawn out to the second element body side face 10d and then connected to the external conductor 22 of the second external conductor group 25 shown in FIG. 1.

Then, the external conductor 12 connecting to the first coil wire path portion 76 and the second coil wire path portion 77 of the first inductor section 30C is connected with the first internal electrodes E57 of the first capacitor section 50Da and the second capacitor section 50Db. Furthermore, the external conductor 22 connecting to the first coil wire path portion 79 and the second coil wire path portion 78 of the second inductor section 30D is connected with the second internal electrodes E58 of the first capacitor section 50Da and the second capacitor section 50Db.

When mounted on the circuit board, the LC composite component 6 is connected thereto so that either the first capacitor section 50Da or the second capacitor section 50Db is located near the circuit board. Accordingly, when compared with the LC composite component 5 of the aforementioned fifth embodiment, the LC composite component 6 has a shorter distance from the circuit board to the first internal electrode E57 or the second internal electrode E58. As a result, the LC composite component 6 can reduce the ESL that may be developed between the first capacitor section 50Da or the second capacitor section 50Db and the circuit board.

As described above, the LC composite component 6 is configured such that the capacitor sections and the inductor section are alternately stacked in layers in the order of the first capacitor section 50Da, the inductor section 30CD, and the second capacitor section 50Db. The first capacitor section 50Da and the second capacitor section 50Db are symmetric with respect to the inductor section 30CD in the layering direction. This allows the first capacitor section 50Da and the second capacitor section 50Db to be disposed on the first element body principal face 10a side and the second element body principal face 10b side of the LC composite component 6, respectively.

The aforementioned structure allows the first internal electrode E57 or the second internal electrode E58 of the first capacitor section 50Da or the second capacitor section 50Db to be located closest to the circuit board, thereby reducing the ESL.

Furthermore, the first coil wire path portion 76 (79) and the second coil wire path portion 77 (78) are connected by an external connection conductor, which is not mounted, thus providing an elongated electrically conductive path. As a result, the electrically conductive path of the spiral coil is elongated, thereby providing an increased inductance component.

The first inductor section 30C and the second inductor section 30D are separately disposed above and below the element body center O in the layering direction. Furthermore, the first internal electrodes E57 and the second internal electrodes E58 are disposed at the same position and the same distance with respect to the element body center O.

Furthermore, the LC composite component 6 is configured such that the first coil wire path portion 76 of the first inductor section 30C and the first coil wire path portion 79 of the second inductor section 30D are disposed at the same position and the same distance with respect to the element body center O. In the same manner, the LC composite component 6 is also configured such that the second coil wire path portion 77 of the first inductor section 30C and the second coil wire path portion 78 of the second inductor section 30D are disposed at the same position and the same distance.

The LC composite component 6 is further configured such that when viewed in the layering direction, the first internal electrodes E57 and the second internal electrodes E58 are symmetric with respect to the element body center O. The LC composite component 6 is also preferably configured such that the first coil wire path portion 76 of the first inductor section 30D and the first coil wire path portion 79 of the second inductor section 30D should be disposed to be symmetric with respect to the element body center O when viewed in the layering direction, while the second coil wire path portion 77 of the first inductor section 30C and the second coil wire path portion 78 of the second inductor section 30D should be disposed to be symmetric about the center O when viewed in the layering direction.

This structure can eliminate the mounting directivity of the LC composite component 6. This can reduce the alignment work of the mounting direction of the LC composite component 6 when the LC composite component 6 is mounted on the circuit board. Furthermore, the aforementioned structure enables the LC composite component 6 to be employed as an LC filter having constant properties because the properties of the LC composite component 6 do not vary depending on the mounting direction.

The first coil wire path portions 76 and 79 and the second coil wire path portions 77 and 78 of the first inductor section 30C and the second inductor section 30D, which have been mentioned above, are preferably wound around at least one of the first principal face electrode portion E512 of the first internal electrode E57 adjacent to the first inductor section 30C and the second principal face electrode portion E522 of the second internal electrode E58 adjacent to the second inductor section 30D when viewed in the layering direction.

The first coil wire path portions 76 and 79 and the second coil wire path portions 77 and 78 of the first inductor section 30C and the second inductor section 30D are wound around on the surface of the insulator layers 36, 37, 38, and 39, avoiding the region opposed in the layering direction to the area of the principal face electrode portions E512 and E522 of the first capacitor section 50Da or the second capacitor section 50Db.

Furthermore, the region of the insulator layers 36, 37, 38, and 39 opposed in the layering direction to the principal face electrode portions D511, D513, D521, and D523 is to be defined as the region through which the first coil wire path portions 76 and 79 and the second coil wire path portions 77 and 78 will not pass. This allows the principal face electrode portions E512 and E522 to less overlap with the first coil wire path portions 76 and 79 and the second coil wire path portions 77 and 78 in the layering direction. As a result, it is possible to reduce the capacitance between the principal face electrode portions E512 and E522 and the first coil wire path portions 76 and 79 as well as the second coil wire path portions 77 and 78. Furthermore, the LC composite component 6 is improved in the properties as a noise filter.

The aforementioned structure prevents the principal face electrode portions of the capacitor sections and the coil wire path portions of the inductor section from overlapping each other in the layering direction. Accordingly, the capacitance between the principal face electrode portions of the capacitor sections and the coil wire path portions of the inductor section will be reduced or not developed. As a result, the LC composite component can attenuate high-frequency noise components.

According to the embodiments of the present invention, it is possible to provide an LC composite component which has no mounting directivity and an increased inductance component, and a structure for mounting the LC composite component.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. An LC composite component comprising:
an element body;
a first external conductor group;
a second external conductor group;
a capacitor section; and
an inductor section,
wherein the element body includes:
a plurality of insulator layers stacked in layers;
a first element body principal face and a second element body principal face which intersect a layering direction of the plurality of insulator layers;
a first element body side face and a second element body side face which couple the first element body principal face and the second element body principal face and which are opposed to each other; and
a first element body end face and a second element body end face which couple the first element body principal face and the second element body principal face together as well as the first element body side face and the second element body side face and which are opposed to each other;
wherein the first external conductor group has three or more external conductors, each being disposed on the first element body side face, and the second external conductor group has three or more external conductors, each being disposed on the second element body side face;
wherein the capacitor section has a first internal electrode and a second internal electrode which are formed on the insulator layers and which are opposed to each other in the layering direction, the first internal electrode being drawn out to the first element body side face and connected to at least one of the external conductors of the first external conductor group, the second internal electrode being drawn out to the second element body side face and connected to at least one of the external conductors of the second external conductor group; and
wherein the inductor section has a first coil wire path portion and a second coil wire path portion which are each formed on any one of the plurality of insulator layers and which are each an electrical conductor pattern,
wherein the capacitor section and the inductor section are alternately stacked in layers in the layering direction, and either one of the capacitor section and the inductor section is disposed both on the first element body principal face side and the second element body principal face side, and
wherein the first coil wire path portion and the second coil wire path portion are connected to the external conductor interposed between the external conductor near the first element body end face and the external conductor near the second element body end face in the first external conductor group, or connected to the external conductor interposed between the external conductor near the first element body end face and the external conductor near the second element body end face in the second external conductor group, and the first coil wire path portion and the second coil wire path portion serve as a coil which is wound in a helical fashion along the layering direction.

2. The LC composite component according to claim 1, wherein
the first internal electrode has a first principal face electrode portion and a first extraction portion, the first extraction portion connecting to the first principal face electrode portion and an external conductor of the first external conductor group,
the second internal electrode has a second principal face electrode portion opposed to the first principal face electrode portion in the layering direction and a second extraction portion, the second extraction portion connecting to the second principal face electrode portion and an external conductor of the second external conductor group, and
the first coil wire path portion and the second coil wire path portion of the inductor section are wound around at least one of the first principal face electrode portion of the first internal electrode and the second principal face electrode portion of the second internal electrode when viewed in the layering direction.

3. The LC composite component according to claim 1, wherein the inductor section is disposed both on the first element body principal face side and on the second element body principal face side.

4. The LC composite component according to claim 1, wherein the capacitor section is disposed both on the first element body principal face side and on the second element body principal face side.

5. The LC composite component according to claim 1, wherein the first coil wire path portion and the second coil wire path portion are adjacent to each other via the insulator layer.

6. The LC composite component according to claim 1,
the inductor section comprising at least one of:
a first inductor section; and
a second inductor section,
wherein the first inductor section includes the first coil wire path portion and the second coil wire path portion, the first coil wire path portion and the second coil wire path portion being drawn out to the first element body side face to which the first internal electrode is drawn out and the first inductor section being adjacent to the first internal electrode in the layering direction,
wherein the second inductor section includes the first coil wire path portion and the second coil wire path portion, the first coil wire path portion and the second coil wire path portion being drawn out to the second element body side face to which the second internal electrode is drawn out and the second inductor section being adjacent to the second internal electrode in the layering direction.

7. The LC composite component according to claim 1,
the inductor section comprising:
a first inductor section; and
a second inductor section,
wherein the first inductor section includes the first coil wire path portion and the second coil wire path portion, the first coil wire path portion and the second coil wire path portion being drawn out to the first element body side face,
wherein the second inductor section includes the first coil wire path portion and the second coil wire path portion, the first coil wire path portion and the second coil wire path portion being drawn out to the second element body side face, and
wherein at least two external conductors other than an external conductor connecting to the first coil wire path portion and the second coil wire path portion of the first inductor section are connected with the first internal electrode of the capacitor section, and at least two external conductors other than an external conductor connecting to the first coil wire path portion and the second coil wire path portion of the second inductor section are connected with the second internal electrode of the capacitor section.

8. The LC composite component according to claim 1, the inductor section comprising:
a first inductor section; and
a second inductor section,
wherein the first inductor section includes the first coil wire path portion and the second coil wire path portion, the first coil wire path portion and the second coil wire path portion being drawn out to the first element body side face,
wherein the second inductor section includes the first coil wire path portion and the second coil wire path portion, the first coil wire path portion and the second coil wire path portion being drawn out to the second element body side face, and
wherein an external conductor connecting to the first coil wire path portion and the second coil wire path portion of the first inductor section is connected with the first internal electrode of the capacitor section, and an external conductor connecting to the first coil wire path portion and the second coil wire path portion of the second inductor section is connected with the second internal electrode of the capacitor section.

9. The LC composite component according to claim 1, wherein the insulator layer having the first coil wire path portion formed thereon and the insulator layer having the second coil wire path portion formed thereon contain a magnetic substance, and the insulator layer having the first internal electrode formed thereon and the insulator layer having the second internal electrode formed thereon contain a dielectric material.

10. The LC composite component according to claim 1,
the inductor section comprising:
a first inductor section; and
a second inductor section,
wherein the first inductor section includes the first coil wire path portion and the second coil wire path portion, the first coil wire path portion and the second coil wire path portion being drawn out to the first element body side face,
wherein the second inductor section includes the first coil wire path portion and the second coil wire path portion, the first coil wire path portion and the second coil wire path portion being drawn out to the second element body side face, the first inductor section and the second inductor section being separately disposed above and below an element body center in the layering direction,
wherein the first internal electrodes and the second internal electrodes are disposed at the same position and the same distance with respect to the element body center, the first internal electrodes are disposed at the same position and the same distance with respect to the element body center, or the second internal electrodes are disposed at the same position and the same distance with respect to the element body center,
wherein, with respect to the element body center, the first coil wire path portion of the first inductor section and the first coil wire path portion of the second inductor section are disposed at the same position and the same distance, while the second coil wire path portion of the first inductor section and the second coil wire path portion of the second inductor section are disposed at the same position and the same distance,
or alternatively, with respect to the element body center, the first coil wire path portion of the first inductor section and the second coil wire path portion of the second inductor section are disposed at the same position and the same distance, while the second coil wire path portion of the first inductor section and the first coil wire path portion of the second inductor section are disposed at the same position and the same distance,
wherein the first internal electrodes and the second internal electrodes are symmetric with respect to the center of the element body when viewed in the layering direction, and
wherein the first coil wire path portion of the first inductor section and the first coil wire path portion of the second inductor section are disposed to be symmetric with respect to the center of the element body when viewed in the layering direction, while the second coil wire path portion of the first inductor section and the second coil wire path portion of the second inductor section are disposed to be symmetric when viewed in the layering direction,
or alternatively, with respect to the center of the element body, the first coil wire path portion of the first inductor section and the second coil wire path portion of the second inductor section are disposed to be symmetric when viewed in the layering direction, while the second coil wire path portion of the first inductor section and the first coil wire path portion of the second inductor section are disposed to be symmetric when viewed in the layering direction.

11. The LC composite component according to claim 6,
the inductor section comprising:
a first inductor section; and
a second inductor section,
wherein the first inductor section includes the first coil wire path portion and the second coil wire path portion, the first coil wire path portion and the second coil wire path portion being drawn out to the first element body side face,
wherein the second inductor section includes the first coil wire path portion and the second coil wire path portion, the first coil wire path portion and the second coil wire path portion being drawn out to the second element body side face, the first inductor section and the second inductor section being separately disposed above and below the element body center in the layering direction,
wherein the first internal electrodes and the second internal electrodes are disposed at the same position and the same distance with respect to the element body center,
wherein with respect to the element body center, the first coil wire path portion of the first inductor section and the first coil wire path portion of the second inductor section are disposed at the same position and the same distance, while the second coil wire path portion of the first inductor section and the second coil wire path portion of the second inductor section are disposed at the same position and the same distance,
or alternatively, with respect to the element body center, the first coil wire path portion of the first inductor section and the second coil wire path portion of the second inductor section are disposed at the same position and the same distance, while the second coil wire path portion of the first inductor section and the first coil wire path portion of the second inductor section are disposed at the same position and the same distance,
wherein the first internal electrodes and the second internal electrodes are symmetric with respect to the element body center when viewed in the layering direction, and
wherein with respect to the element body center, the first coil wire path portion of the first inductor section and the first coil wire path portion of the second inductor section are disposed to be symmetric when viewed in the layering direction, while the second coil wire path portion of the first inductor section and the second coil wire path portion of the second inductor section are disposed to be symmetric when viewed in the layering direction,
or alternatively, with respect to the element body center, the first coil wire path portion of the first inductor section and the second coil wire path portion of the second inductor section are disposed to be symmetric when viewed in the layering direction, while the second coil wire path portion of the first inductor section and the first coil wire path portion of the second inductor section are disposed to be symmetric when viewed in the layering direction.

12. The LC composite component according to claim 10, wherein the external conductors of the first external conductor group and the external conductors of the second external conductor group are disposed to be symmetric with respect to the element body center when the first element body principal face is viewed in the layering direction.

13. A mounting structure for mounting the LC composite component according to claim 1 onto a circuit board including signal lines and a GND lines, wherein the LC composite component is mounted onto the circuit board in a manner such that
an external conductor of the first external conductor group connecting to the first coil wire path portion and the second coil wire path portion serves as an external connection conductor which is not mounted on the circuit board, the two external conductors of the first external conductor group other than the external connection conductor are connected to the signal lines, and
the external conductor connecting to the second internal electrode of the second external conductor group is connected to the GND line.
